(19) United States
(12) Patent Application Publication
(10) Pub. No.: US 2003/0094593 A1
(43) Pub. Date: May 22, 2003

(54) Silica and a silica-based slurry

(76) Inventors: Stuart D. Hellring, Pittsburgh, PA (US); Colin P. McCann, Pittsburgh, PA (US); Suryadevara V. Babu, Potsdam, NY (US); Yuzhuo Li, Potsdam, NY (US); Satish Narayanan, Hillsboro, OR (US)

Correspondence Address: PPG INDUSTRIES INC, INTELLECTUAL PROPERTY DEPT, ONE PPG PLACE, PITTSBURGH, PA, 15272, US

(21) Appl. No.: 09/882,549

(22) Filed: Jun. 14, 2001

(51) Int. Cl. B44C 1/22; H01L 21/302

(52) U.S. Cl. 252/79.1; 216/38

(57) ABSTRACT

This invention relates to a silica, a slurry composition, and a method of their preparation. In particular, the silica of the present invention includes aggregated primary particles. The slurry composition which incorporates the silica, is suitable for polishing articles and especially useful for chemical-mechanical planarization of semiconductor substrates and other microelectronic substrates.

### DESCRIPTION OF THE INVENTION

This invention relates to a silica, a slurry composition, and a method of their preparation. In particular, the silica of the present invention includes aggregated primary particles. The slurry composition which incorporates the silica, is suitable for polishing articles and especially useful for chemical-mechanical planarization (“CMP”) of semiconductor substrates and other microelectronic substrates.

In general, a plurality of integrated circuits are formed on a semiconductor substrate to fabricate a semiconductor wafer. The integrated circuits are typically formed by a series of process steps in which patterned layers of materials, such as conductive, insulating and semiconducting materials, are formed on the substrate. The use of copper and tantalum metal interconnects on semiconductor substrates is known in the art. In general, copper serves as an electrically conductive interconnection that is surrounded by an insulating interlayer dielectric material (ILD) such as silicon dioxide, and tantalum serves as a barrier between the copper and the ILD to prevent copper migration into the ILD. CMP is a technique known for removing such metallic materials from a semiconductor substrates. The control of metal removal rates, and selectivity between copper, tantalum, tungsten, aluminum and ILD, for example, is desirable for achieving planarity requirements.

The CMP of a rough surface of an article such as a semiconductor substrate, to a smooth surface generally involves rubbing the rough surface with the work surface of a polishing pad using a controlled and repetitive motion. Thus, the process typically involves rotating the polishing pad and semiconductor substrate against each other in the presence of a fluid. The fluid may contain a particulate material such as alumina, ceria, silica or mixtures thereof. The pad and particulate material act to mechanically planarize the semiconductor substrate, while the fluid and particulate material serve to chemically planarize the substrate and to facilitate the removal and transport of abraded material off and away from the rough surface of the article.

In order to maximize the density of integrated circuits on a semiconductor wafer, it is necessary to have an extremely planar substrate at various stages throughout the semiconductor wafer production process. As such, semiconductor wafer production typically involves at least one, and typically a plurality of planarization steps.

It is known in the art to use alumina and silica abrasives in the CMP process. U.S. Pat. No. 5,980,775 discloses a CMP composition which includes an oxidizing agent, at least one catalyst, at least one stabilizer and a metal oxide abrasive such as alumina or silica. Further, this patent discloses a method for using the CMP composition to polish at least one metal layer of a substrate. U.S. Pat. No. 6,136,711 discloses a CMP composition which includes a compound capable of etching tungsten, at least one inhibitor of tungsten etching, and a metal oxide abrasive such as alumina or silica. Further, this patent discloses a method for using the CMP composition to polish substrates containing tungsten. U.S. Pat. No. 5,904,159 discloses a polishing slurry comprising a dispersed silica which is obtained by dispersing fumed silica particles in an aqueous solvent, wherein the average primary particle size is from 5 to 30 nm, having a light scattering index of from 3 to 6 and a silica concentration of 1.5% by weight, and an average secondary particle size of from 30 to 100 nm on a weight basis.

In general, the use of alumina has been considered desirable in the art because alumina particles have lower chemical reactivity than silica particles on silicon dioxide, and thus, alumina particles demonstrate a higher metal selectivity than silica particles. Without high selectivity, undesirable amounts of the silicon dioxide layer may be polished away with the metal. However, alumina slurries are generally more costly, and more prone to defects than silica slurries. Generally, alumina particles are more difficult to disperse than silica particles. Thus, it is desirable to develop a silica slurry that exhibits controlled removal rates and high selectivity relative to various metallic materials.

“Selectivity” as used herein refers to the ratio of removal rates of two or more materials during CMP. For example, the selectivity of copper to tantalum represents the ratio of the removal rate of copper to the removal rate of tantalum.

It has now been found that slurry compositions containing silica having the defined characteristics of the present invention provide performance advantages relative to metal removal rates and selectivity.

In accordance with the present invention, there is provided a silica comprising (i) an aggregate of primary particles, said primary particles having an average diameter of at least seven (7) nanometers, wherein said aggregate has an aggregate size of less than one (1) micron; and (ii) a hydroxyl content of at least seven (7) hydroxyl groups per nanometer squared. In an embodiment, these defined characteristics of the silica of the present invention were obtained using a precipitated silica.

The present invention also includes a silica-based slurry comprising said silica of the present invention.

The features that characterize the present invention are pointed out with particularity in the claims which are part of this disclosure. These and other features of the invention, its operating advantages and the specific objects obtained by its use will be more fully understood from the following detailed description and the operating examples.

Other than in the operating examples, or where otherwise indicated, all numbers or expressions, such as those expressing structural dimensions, pressures, flow rates, etc, used in the specification and claims are to be understood as modified in all instances by the term “about”.

### DETAILED DESCRIPTION OF THE INVENTION

In general, a silica may be prepared by combining an aqueous solution of a soluble metal silicate with an acid. The soluble metal silicate is typically an alkali metal silicate such as sodium or potassium silicate. The acid may be selected from the group consisting of mineral acids, organic acids, and carbon dioxide. The silicate/acid slurry may then be aged. An acid or base is added to the silicate/acid slurry. The resultant silica particles are separated from the liquid portion of the mixture. The separated silica is washed with water, the wet silica product is dried, and then the dried silica is separated from residues of other reaction products, using conventional washing, drying and separating methods.

It is known in the art that when silicate polymerizes to a sufficient molecular weight such that the polymer size exceeds about one (1) nanometer, discrete silica particles form. These particles are referred to herein as “primary” particles. Methods for characterizing primary particles have been described in prior art references (e.g., “The Chemistry of Silica,” Ralph K. Iler, 1979 John Wiley & Sons, New York, Chapter 5).

In an embodiment of the present invention, the primary particles have an average diameter of at least 7 nanometers, or at least 10 nanometers, or at least 15 nanometers. As used herein, the average diameter of the primary particles of the silica in the present invention is calculated using CTAB specific surface area. The calculation includes dividing 2720 by the CTAB specific surface area in square meters per gram. This method is analogous to that described by the Iler reference (ibid page 465) for amorphous silica with a skeletal density of 2.2 grams per cubic centimeter.

Further, in an embodiment of the present invention, the primary particles may be approximately spherical.

It is known in the art that primary particles having a particle size that is less than about 100 nanometers show a tendency to group together and form covalent siloxane bonds between the particles (e.g., “Iler”), in addition to the siloxane bonds within the primary particles. These groups of covalently-bonded primary particles are referred to herein as “aggregates”. Methods for characterizing aggregates have also been described in the prior art (e.g., “Iler”).

The bonds between the primary particles of the silica which is used to prepare the silica of the present invention, are sufficiently weak such that the bond(s) may rupture when mechanical shear is applied using commercially available equipment such as a conventional homogenizer, Nanomiser™, or Microfluidizer™. The silica of the present invention includes aggregated primary particles having an aggregate size of less than one (1) micron, or less than 0.5 micron. In an embodiment of the present invention, the bonds between the primary particles of the silica rupture to provide a dispersion or slurry wherein the aggregate size is less than one (1) micron, or less than 0.5 micron.

The size of the aggregates may be determined by methods that are known to the skilled artisan, e.g., using light scattering techniques, such as a Coulter LS particle size analyzer. As used herein and in the claims, “aggregate size” is defined as the diameter of the aggregate based on volume percent as determined by light scattering using a Coulter Counter LS particle size analyzer. In this light scattering technique, the diameter is determined from a hydrodynamic radius of gyration regardless of the actual shape of the aggregate. The “average” aggregate size is the average diameter of the aggregate based on volume percent. In an embodiment of the present invention, the average aggregate size is from 75 to 250 nm.

The silica used to prepare the silica of the present invention, is such that the aggregates of the primary particles are capable of “breaking down” into smaller aggregates of primary particles when subjected to a particle size reduction technique. The process conditions for manufacturing the silica are such that they favor the formation of aggregates which are prone to breaking down into smaller aggregates. It is believed that the aggregates which are prone to breaking down are due to silica aggregates with fewer siloxane bonds between the primary particles.

It is further believed that oil absorption is a measure of the openness of the silica structure and an indication of the susceptibility of the silica to undergo particle size reduction. In the present invention, at least 50% of the aggregated primary particles are reduced to an aggregate size of less than one (1) micron. In an embodiment, at least 80%, and preferably 100% of the aggregated primary particles are reduced to an aggregate size of less than one (1) micron. As used in the present specification and claims, dibutyl phthalate (DBP) oil absorption of the amorphous precipitated silica is determined according to ASTM D 2414-93 using dibutyl phthalate as the absorbate. The silica of the present invention typically has an oil absorption of at least 150 milliliters per 100 grams of silica. In an embodiment, the oil absorption is at least 220 milliliters per 100 grams of silica.

Oil absorption, however, cannot be solely relied on as an indicator of the susceptibility of a silica to undergo particle size reduction. Inter-particle bridging in some cases may reinforce a silica aggregate and prevent the silica from breaking-down even though the oil absorption may be high. As an alternative, microscopy may be employed to give a physical measurement of the extent of material bridging between primary particles.

In an embodiment of the present invention, the silica is a precipitated silica. The silica of the present invention, has a “surface roughness” of at least 1.0 when defined by the ratio of the BET-nitrogen (5-point) surface area to CTAB specific surface area. As used herein, the term “BET surface area” is determined by the Brunauer, Emmett, and Teller (BET) method according to ASTM D1993-91. The term “surface roughness” as used herein is defined in a manner analogous to the “roughness factor” that was described by Anderson and Emmett as the ratio of BET nitrogen surface area to the surface area determined electron micrographs [cf. R. B. Anderson and P. H. Emmett Journal of Applied Physics 1939, 19, 367]. The surface area by electron micrograph is herein substituted by CTAB specific surface area.

The BET surface area was determined by fitting five relative-pressure points from a nitrogen sorption isotherm measurement that was made with a Micromeritics TriStar 3000™ instrument. A FlowPrep-060™ station provided heat and a continuous gas flow to prepare samples for analysis. Prior to nitrogen sorption, the silica samples were dried by heating to a temperature of 160° C. in flowing nitrogen (P5 grade) for a minimum of one (1) hour.

The CTAB specific surface area is a measure of the external surface area of the silica. The French Standard Method (French Standard NFT 45-007, Primary Materials for the Rubber Industry: Precipitated Hydrated Silica, Section 5.12, Method A, pp. 64-71, November 1987) measures the external specific surface area by determining the quantity of CTAB (CetylTrimethylAmmonium Bromide) before and after adsorption at a pH of from 9.0 to 9.5, using a solution of the anionic surfactant Aerosol OT® as the titrant. Unlike other CTAB methods which use filtration to separate the silica, the French Standard Method uses centrifugation. The quantity of CTAB adsorbed for a given weight of silica and the space occupied by the CTAB molecule are used to calculate the external specific surface area of the silica. The external specific surface area value is as square meters per gram. The detailed procedure used to determine CTAB is set forth in the Examples.

The surface area and surface roughness of a silica may depend on the method used to prepare the silica. In an embodiment, the silica which was then used to prepare the silica of the present invention, was prepared by employing a precipitation process. In general, a lower temperature and higher hydroxide content during the precipitation step produces a silica having a high CTAB specific surface area. A higher temperature and a longer period of aging following the precipitation step, typically minimizes surface roughness.

In an embodiment, the surface roughness of the silica may be increased for a given primary particle size by changing precipitation conditions. For example, the hydroxide concentration may be increased during the “aging” step (Step I.e., for example, of the process described below) by adding a base such as a hydroxide to the mixture. The amount of hydroxide added may be such that the silica to hydroxide mole ratio is above 2.9. In an embodiment, the silica to hydroxide mole ratio is from 3.3 to 10; and in another embodiment, from 4.0 to 6.6. The hydroxide may be selected from a wide variety of known hydroxides, such as potassium hydroxide. The increased hydroxide concentration results in a significantly higher BET surface area, however, the CTAB specific surface area is unchanged or slightly decreased. This method may generally be used for increasing the surface roughness of a silica having a low CTAB surface area. A “low” CTAB surface area is typically less than 100 m²/g.

In another embodiment, the silicate and acid flow rates are balanced throughout the silicate and acid addition step (Step I.c., for example, of the process as described below), to maintain a higher silicate to acid flow rate ratio. In this embodiment, the higher hydroxide concentration decreases the level of silicate neutralization during the addition step. This method may generally be used to increase the surface roughness of a silica having a high CTAB surface area. A “high” CTAB surface area is typically greater than 100 m²/g.

Further, varying the duration of the aging step may also be used to modify the surface roughness of a silica when the reaction mixture has a pH of 8.5 or below (Step 1I.d., for example, of the process as described below). In this pH range, a longer aging period typically results in a lower surface roughness.

A method of preparing a silica which may then be used in preparing the silica of the present invention, may include dissolving a solid-form of an alkali metal silicate in water to produce an “additive” solution. Or, a concentrated solution of an aqueous alkali metal silicate may be diluted to obtain the desired concentration of alkali metal in the “additive” solution. Herein, the weight amount of alkali metal is analytically reported as “M₂O”. The alkali metal silicate may be selected from the group consisting of lithium silicate, sodium silicate, potassium silicate, and mixtures thereof.

The silica preparation processes as described herein, are carried out at a temperature which is sufficiently high to preclude gelation of the reaction mixture. Thus, the temperature is typically at least 70° C. Further, the temperature at which the preparation processes are carried out is sufficiently low to avoid boiling of the reaction mixture and the phase transition to crystallization when the process is conducted in a non-pressurized vessel. Thus, the temperature is typically not higher than 100° C. Moreover, the amount of SiO₂ and M₂O used in the processes is selected relative to the gelation and crystallization concerns.

The resultant “additive” solution typically contains from 1 to 30 weight percent SiO₂ and has a SiO₂:M₂O molar ratio of from 0.1 to 3.9. In an embodiment, the “additive” solution contains from 10 to 25 percent by weight SiO₂; and in another embodiment, 15 to 20 weight percent SiO₂. Further, in an embodiment, the SiO₂:M₂O molar ratio is from 2.9 to 3.5. In another embodiment the SiO₂:M₂O molar ratio is from 3.0 to 3.4; and in another embodiment, from 3.1 to 3.4.

A method of preparing a silica having a low CTAB specific surface area for use in the present invention may include the following steps. As aforementioned, the term “low CTAB specific surface area” typically refers to a value of about 100 meters squared per gram or less.

(I.a.) A portion of the “additive” aqueous alkali metal silicate solution is diluted with water to prepare an “initial” aqueous alkali metal silicate solution.

This “initial” solution contains from 0.1 to 2.0 weight percent Sio₂ and has a SiO₂:M₂O molar ratio of from 0.1 to 3.9. In an embodiment, the aqueous alkali metal silicate solution comprises from 0.2 to 1.5 weight percent SiO2; or from 0.3 to 1.0 weight percent SiO₂. Further, in an embodiment, the SiO₂:M₂O molar ratio is from 1.6 to 3.9; or from 2.9 to 3.5; or from 3.1 to 3.4.

(I.b.) An acid is added to the “initial” aqueous alkali metal silicate solution to neutralize the M₂O that is present, to form a first reaction mixture. Further, in an embodiment, at least 90 percent of the M₂O present in the initial aqueous alkali metal silicate solution is neutralized. As much as 100 percent of the M₂O may be neutralized. In an embodiment of the present invention, from 95 to 100 percent of the M₂O is neutralized.

The percent neutralization may be calculated by assuming that one (1) equivalent of strong acid neutralizes one (1) equivalent of M₂O. For instance, 1 mole (2 equivalents) of sulfuric acid neutralizes 1 mole (2 equivalents) of M₂O. In an embodiment, the pH is adjusted to less than 9.5, or less than 9.0, or 8.5 or less. Suitable acids for use in this neutralization step may vary widely. In general, the acid should be strong enough to neutralize the alkali metal silicate. Examples of such acids include sulfuric acid, hydrochloric acid, nitric acid, phosphoric acid, formic acid, acetic acid, and mixtures thereof. In an embodiment, sulfuric acid, hydrochloric acid, nitric acid or phosphoric acid is used. In another embodiment, sulfuric acid is used.

(I.c.) Another portion of the “additive” aqueous alkali metal silicate solution and acid are added, preferably simultaneously, to the first reaction mixture over a period of time to form a second reaction mixture. In an embodiment of the present invention, the addition is completed in a period of from 20 to 180 minutes; or from 30 to 120 minutes; or from 45 to 90 minutes. The amount of “additive” solution used is such that the amount of Sio₂ added is from 0.5 to 30 times the amount of SiO₂ present in the “initial” aqueous alkali metal silicate solution. In an embodiment, from 3 to 28 times the SiO₂ present in the “initial” solution is added. In another embodiment of the present invention, the amount of acid which is added is such that at least 90 percent of the M₂O contained in the “additive” solution added during the simultaneous addition is neutralized. In an embodiment, at least 95 percent of the M₂O is neutralized; and in another embodiment, 100 percent of the M₂O is neutralized. In an embodiment the pH is maintained at less than 9.5, or less than 9.0, or 8.5 or less.

Suitable acids for use in this second neutralization step may vary widely. As aforementioned, the acid should be strong enough to neutralize the alkali metal silicate. Examples of such acids include sulfuric acid, hydrochloric acid, nitric acid, phosphoric acid, formic acid, acetic acid, and mixtures thereof. In an embodiment, sulfuric acid, hydrochloric acid, nitric acid or phosphoric acid is used. In another embodiment, sulfuric acid is used.

(I.d.1.) If a silica having a low surface roughness is desired, acid is added to the second mixture with agitation to form a third reaction mixture. As used herein, “low” surface roughness refers to a silica having a BET surface area to CTAB specific surface area ratio less than 1.2 or less. The amount of acid used is such that the pH of the third reaction mixture is 9.3 or lower. In an embodiment, the pH is from 7.0 to 9.3; and in another embodiment, from 7.5 to 9.0. A wide variety of acids may be used in this step. The acid should be selected such that the acid is strong enough to reduce the pH to a value within said pH ranges. In an embodiment, suitable acids include sulfuric acid, hydrochloric acid, nitric acid, phosphoric acid, formic acid, and acetic acid. In another embodiment, sulfuric acid, hydrochloric acid, nitric acid or phosphoric acid is used; and in a further embodiment, sulfuric acid is used.

(I.d.2.) If a silica having a high surface roughness is desired, hydroxide is added to the second reaction mixture with agitation to form a third reaction mixture. As used herein, “high” surface roughness refers to a silica having a BET surface area to CTAB specific surface area ratio of 1.2 or higher. The amount of hydroxide added is such that the silica to hydroxide mole ratio is greater than 2.9. In an embodiment, the silica to hydroxide mole ratio is from 3.3 to 10; and in another embodiment, from 4.0 to 6.6. The hydroxide used in this step may vary widely. Examples of suitable hydroxides include ammonium hydroxide, potassium hydroxide, sodium hydroxide, organic ammonium hydroxides, hydroxides of organic amines, and mixtures thereof.

(I.e.) Either of the third reaction mixtures (for low or high surface roughness) may be aged with agitation. In an embodiment, the period of aging is from 10 to 100 minutes; and in another embodiment, from 20 to 90 minutes.

(I.f.) Acid is then added to the third reaction mixture while agitating to form a fourth reaction mixture. The amount of acid added is such that the pH of the fourth reaction mixture is less than 7.0. In an embodiment, the pH is from 3.0 to 6.0; and in another embodiment, from 3.5 to 4.5. The acid used in this step may vary widely. As stated previously, the acid used should be strong enough to reduce the pH of the mixture to within the specified ranges. Examples of such acids include sulfuric acid, hydrochloric acid, nitric acid, phosphoric acid, formic acid, and acetic acid. In an embodiment of the present invention, sulfuric acid, hydrochloric acid, nitric acid, and phosphoric acid are used. In another embodiment, sulfuric acid is used.

In an embodiment, a silica having a high CTAB specific surface area for use in the present invention may be prepared according to the following process.

(II.a.) A portion of the “additive” aqueous alkali metal silicate solution may be diluted with water to produce an “initial” aqueous alkali metal silicate solution containing from 0.1 to 5.0 weight percent SiO₂ and having hydroxide content of from 0.02 mol per liter to 0.35 mol per liter. Additional hydroxide may be added to this initial aqueous alkali metal silicate solution to adjust the hydroxide content to from 0.02 mol per liter to 0.35 mol per liter. In an embodiment, the initial aqueous alkali metal silicate solution comprises from 0.2 to 4.0 weight percent SiO₂; or from 0.3 to 3.0 weight percent SiO₂. Further, in an embodiment, the hydroxide content is from 0.02 mol per liter to 0.26 mol per liter; or from 0.03 mol per liter to 0.22 mol per liter.

The hydroxide content, in mol per liter, of a reaction mixture may be determined by the following process. A sample of the reaction mixture is diluted with approximately 100 milliliters of deionized water using 0.645 N hydrochloric acid in the presence of phenolphthalein indicator; and the sample is titrated. The hydroxide content, in mol per liter, is then calculated by multiplying the milliliters of 0.645 N HCl used in the above titration, by the normality of the titrant, and dividing by the volume, in milliliters, of the reaction mixture.

(II.b.) Over a period of time, with agitation, a portion of the additive aqueous alkali metal silicate solution and acid are added, preferably simultaneously, to the first reaction mixture thereby forming a second reaction mixture. The amount of additive aqueous alkali metal silicate solution used is such that the amount of SiO₂ added is from 0.5 to 30 times the amount of SiO₂ present in the initial aqueous alkali metal silicate solution established in step (II.a.). The amount of acid added is such that the hydroxide content established in step (II.a.) is maintained. In an embodiment, the amount of SiO₂ added is from 3 to 28 times the amount of Sio₂ present in the initial aqueous alkali metal silicate solution established in step (II.a.). This addition step may be completed over a period of 20 to 180 minutes. In another embodiment, this addition step is completed over a period of 30 to 120 minutes, or from 45 to 90 minutes.

(II.c.) Acid is added to the second mixture with agitation to form a third reaction mixture. The amount of acid used is such that the pH of the third reaction mixture is 9.3 or lower. In an embodiment, the pH is from 7.0 to 9.3; and in another embodiment, from 7.5 to 9.0. A wide variety of acids may be used in this step. The acid selected should be strong enough to reduce the pH to a value within the aforementioned specified ranges. In an embodiment, suitable acids include sulfuric acid, hydrochloric acid, nitric acid, phosphoric acid, formic acid, and acetic acid. In another embodiment, sulfuric acid, hydrochloric acid, nitric acid or phosphoric acid is used; and in a further embodiment, sulfuric acid is used.

(II.d.) The third reaction mixture may be aged with agitation for a period of from 10 to 120 minutes; or from 20 to 90 minutes.

(II.d.1.) In an embodiment, a silica having a low surface roughness may be produced by aging the third reaction mixture for a time period longer than 30 minutes. In another embodiment, the aging step is for a time period of more than 60 minutes. As aforementioned, “low” surface roughness as used herein refers to a silica having a BET surface area to CTAB specific surface area ratio of less than 1.2.

(II.d.2.) In an embodiment, a silica having a low surface roughness may be produced by aging the third reaction mixture for a time period of 120 minutes or less. In another embodiment, the aging step is carried out for a period of 30 minutes or longer. As aforementioned, “high” surface roughness as used herein refers to a silica having a BET surface area to CTAB specific surface area ratio of 1.2 or higher.

(II.e.) Acid is then added to the third reaction mixture while agitating to form a fourth reaction mixture. The amount of acid added is such that the pH of the fourth reaction mixture is below 7.0. In an embodiment, the pH is from 3.0 to 6.0; and in another embodiment, from 3.5 to 4.5. The acid used in this step may vary widely. As stated previously, the acid should be selected such that the acid is strong enough to reduce the pH of the mixture to within the specified ranges. Examples of such acids include sulfuric acid, hydrochloric acid, nitric acid, phosphoric acid, formic acid, and acetic acid. In an embodiment of the present invention, sulfuric acid, hydrochloric acid, nitric acid, and phosphoric acid are used. In another embodiment, sulfuric acid is used.

The process for preparing a silica having a high CTAB specific surface area and the process for preparing a silica having a low CTAB specific surface area, as discussed above, may further include the following steps.

(III.a.) The silica produced in the fourth reaction mixture is separated from most of the liquid of the aged fourth reaction mixture. This separation may be accomplished by one or more techniques known in the art for separating solids from liquid; such as, for example, filtration, centrifugation, decantation, and the like.

(III.b.) The separated silica is then washed using any of the known procedures for washing solids, such as, for example, passing water through a filter cake, and reslurrying the silica in water followed by separating the solids from the liquid. One washing cycle or a succession of washing cycles may be employed as desired. A purpose of washing the silica is to remove salt formed by the various neutralizations to desirably low levels. The silica is typically washed until the concentration of salt in the dried silica is less than or equal to 2 weight percent. In an embodiment, the silica is washed until the concentration of salt is less than or equal to 1 weight percent.

(III.c.) The washed silica is then dried using one or more techniques known to a skilled artisan. For example, the silica may be dried in an air oven or in a vacuum oven. In an embodiment, the silica is dispersed in water and spray dried in a column of hot air. The temperature at which drying is accomplished is not critical. In an embodiment, the drying temperature is below the fusion temperature; thus, the drying temperature is typically less than 700° C. The drying process may be continued until the silica has the characteristics of a powder.

In general, the dried silica is not completely anhydrous but contains “bound” water (e.g., from 1 to 5 weight percent) and moisture which is not bound water (e.g., from 1 to 15 weight percent) in varying amounts. The latter may be dependent upon the prevailing relative humidity and by loss in weight of the sample from vacuum drying. “Bound” water is defined herein as that water which is removed by additional heating of the silica at calcination temperatures, for example, from 1000° C. to 1200° C. In the present invention, the bound water value is used to calculate the number of hydroxyl groups per gram of moisture-free silica. In this calculation, it is assumed that there are two surface hydroxyls for each mole of bound water. The number of hydroxyl groups per nm² is calculated according to the following equation:

Hydroxyls per nm²=2*10^{-18*}N*bound water*(CTAB specific surface area)⁻¹

Wherein the bound water is given as moles per gram of silica; the CTAB specific surface area is given as meters squared per gram of silica, and N is Avogadro's number (6.023*1023 hydroxyls per mole).

The surface of a silica generally contains hydroxyl groups from siloxane-chain terminating silanols. The number of hydroxyl groups per unit of surface area of silica will vary according to the process used to prepare the silica. In an embodiment, the number of hydroxyl groups per nm² is at least 7, or at least 10, or at least 15. In embodiments of the present invention, these parameters are typically representative of silica prepared by a precipitation process.

The role of hydroxyl groups relative to material removal rates for CMP using a silica-based slurry has been suggested in the art. For example, it has been suggested that the hydroxyl groups of the silica in the slurry bond with hydroxyl groups in the silicon dioxide ILD to chemically facilitate ILD removal (see L. M. Cook, Journal of Non-Crystalline Solids, 1990, 120, 152-171). The affect of hydroxyl groups on copper and tantalum removal rates in CMP using a slurry that contains fumed silica has also be suggested (see Li, Y. and Babu, S. V., “Chemical Mechanisms in CMP of Cu and Ta using Silica Abrasives,” Fifth Annual CMP Symposium 2000, Aug. 14, 2000, Lake Placid, N.Y., and Li.; Jindal, A; and Babu, S. V., Role of Chemicals and Abrasive Particle Properties in Chemical-Mechanical Polishing of Copper and Tantalum, Proc. The Electrochemical Society 198^{th} Meeting, Phoenix, Ariz., Oct. 22-27, 2000).

The determination of weight percent moisture involves a method for measuring the loss in weight of the sample resulting from vacuum drying at approximately 105° C. A procedure is described in ASTM Standards, Method A of D-280, Volume 06.02. A silica sample is dried at 105±3° C. in a weighing bottle at atmospheric pressure. After approximately 30 minutes, a vacuum is engaged and the sample is dried in vacuo for an additional 30 minutes. The weight loss from the original sample is the moisture loss, and is used to calculate weight percent moisture.

The bound water per gram of silica is determined as follows. The total weight loss per gram of silica is measured by gravimetric ignition after heating the silica from room temperature to 1150C for one hour. The moisture loss (as described above) is subtracted from the total weight loss. Further, the weight losses per gram of chlorine and sulfur trioxide that occur during ignition are also subtracted from the total weight loss. Chlorine and sulfur trioxide content are calculated from chloride salts and sulfate salts content in the silica, respectively. The concentrations of chloride and sulfate salts that are used for this calculation are determined by x-ray fluorescence measurements on the silica. Thus, the bound water per gram of silica is calculated by the formula:

Bound water=total weight loss−moisture loss−chlorine loss−sulfur trioxide loss

Wherein as aforementioned, the values for total weight loss, chlorine loss and sulfur trioxide loss are given per gram of silica and at a temperature of 1150° C. The value for moisture loss is given per gram of silica and at a temperature of 105° C.

In general, for the silica preparation method described above, the degree of agitation used in the various steps may vary considerably. The agitation employed during the addition of one or more reactants should be at least sufficient to provide a thorough dispersion of the reactants and reaction mixture so as to avoid more than trivial locally high concentrations of reactants and to ensure that silica deposition occurs substantially uniformly. The agitation employed during aging should be at least sufficient to avoid settling of solids to ensure that silica deposition occurs substantially uniformly throughout the mass of silica particles rather than on those particles at or near the top of a settled layer of particles.

As previously mentioned, the silica used to prepare the silica of the present invention is such that the aggregated primary particles are capable of “breaking down” into smaller aggregates of primary particles when subjected to a particle size reduction technique. Such techniques are known in the art and may be exemplified by grinding and pulverizing. In an embodiment, a wet milling process such as a fluid energy milling process may be used for reducing the size of particles. This milling process includes the use of air or superheated steam as the working fluid. Fluid energy mills have been described in the prior art (e.g., Perry's Chemical Engineers Handbook, 4th Edition, McGraw-Hill Book Company, New York, (1963), Library of Congress Catalog Card Number 6113168, pages 8-42 and 8-43; McCabe and Smith, Unit Operations of Chemical Engineering, 3rd Edition, McGraw-Hill Book Company, New York (1976), ISBN 0-07-044825-6, pages 844 and 845; F. E Albus, “The Modern Fluid Energy Mill”, Chemical Engineering Progress, Volume 60, No. 6 (June 1964), pages 102-106, the entire disclosures of which are incorporated herein by reference).

In the fluid energy milling process, the aggregated primary particles of the silica are suspended in a gas stream and circulated at a high velocity in a circular or elliptical path, within a confined chamber. Some reduction of the aggregate particle size occurs when the particles strike or rub against the walls of the confining chamber, but most of the reduction is believed to be caused by inter-particle attrition.

In another embodiment, silica is dispersed by directly contacting the silica with a high-pressure water jet. The resulting aqueous-slurry stream is then carried into a cavitation chamber, which contains an alternating series of narrow-bore and wide-bore cells. A second high-pressure water jet is directed into the cavitation chamber in an opposing flow direction to enhance silica-particle impingement within the cells.

In another embodiment, the silica of the present invention is prepared by reducing the aggregate size of a silica using a double-jet cell process that is related to the apparatus and method disclosed in WO 00/39056 and U.S. Pat. No. 5,720,551. The process as disclosed in these references uses a double jet cell to produce emulsions by reducing droplet size in a water-oil mixture.

In an embodiment of the present invention, a double-jet cell process is useful for producing a silica for use in a slurry for CMP of semiconductors since it is desirable for the aggregates in the silica to have an aggregate size of less than one (1) micron to prevent wafer scratching. In an embodiment, the double-jet cell process includes an apparatus containing two nozzles; each nozzle delivers a jet of fluid along a path. The nozzles are oriented essentially opposite one another. Thus, a first jet of fluid is directed toward a second jet of fluid, and the two jets of fluid interact in a region in an elongated chamber The nozzles may be ceramic such as alumina, sapphire, or diamond coated such that wear from the fluid jet is reduced. In an embodiment, said fluid comprises water. The elongated chamber is configured to form a stream of fluid from the two jets that follows a path that has essentially the opposite direction from one of the paths of one of the jets. To reduce particle size, the chamber includes one or more reactors, which may have different characteristics (e.g., inner diameter, contour, and composition). In an embodiment, twelve (12) or less reactors are used, or four (4) to eight (8) reactors. Seals may be positioned between the reactors. The seals may have different seal characteristics (e.g., inner diameter). The ratio of internal diameter of the seals to that of the reactors is greater than one (1), or greater than two (2).

The two jets of fluid are ejected from two nozzle orifices having different diameters. The velocity of one jet of fluid is dominate and the velocity of the other jet of fluid is recessive. The ratio of the two jet velocities will affect the mean residence time of any given particle in the elongated chamber. The closer the recessive (or lower) jet velocity is to the velocity of the dominant (or higher) jet, the more flow reversal will occur. This backflow will increase particle impingement, and thereby enhance particle size reduction of the aggregate in the silica. The internal diameter of a reactor in the elongated chamber may be used to approximate the nozzle size of the recessive jet. The ratio of the orifice diameters of the two nozzles may be greater than 1:1, but less than 2:1. In an embodiment, the ratio is 1.05:1 to 1.3:1.

The double-jet cell apparatus also includes an outlet port which is configured near the nozzle which discharges the lower velocity jet. The outlet port emits a stream of fluid from the elongated chamber. An inlet port is included in the region of the elongated chamber wherein the nozzle which discharges the high velocity jet is positioned. The inlet port may be used to receive a third fluid, and discharges the third fluid toward the nozzle discharge of the higher jet velocity. In an embodiment of the present invention, the third fluid comprises silica. In another embodiment, the silica is precipitated silica, or a spray dried silica. In other embodiments, the third fluid may further comprise a gas such as air, or a liquid such as water. A pressure drop across the nozzle produces a vacuum at this inlet port.

The silica may be fed into the inlet port from a mechanical feeder such as a screw feeder Or, the silica may be added into the inlet port by drawing the silica through a feed tube into the inlet port by vacuum. Fluid pressure into the two nozzles must be such that the jets of fluid obtain a sufficient velocity to reduce the aggregate size of the silica. Generally, sufficient particle-size reduction uses pressures exceeding 30,000 psig, or in excess of 40,000 psig, for jets of fluid discharged from nozzles with orifices in the range of 0.1 to 0.15 millimeters.

The jets of fluid may contain chemicals, such as polyacrylamide copolymers, that are known to reduce nozzle wear and reduce energy consumption in water-jet technology. The jets of fluid may contain other chemicals, such as surfactants and thickeners, to prevent particle flocculation. Other soluble formulation components may be added to the jets of fluid rather than added to the slurry after particle size reduction of the silica.

In another embodiment, the silica may be dispersed without drying by passing the liquefied product through a high-pressure homogenizer to reduce the aggregate size. Multiple passes through the homogenizer may be necessary to optimize the aggregate size. A pre-dispersion of silica in fluid may also be subjected to particle size reduction through a homogenizer.

In an embodiment, the silica of the present invention may be used to prepare a slurry As used herein and in the claims, the term “slurry” refers to mixture of silica and a liquid. In an embodiment, the liquid may be water. The slurry of the present invention may be composed of a mixture of silicas having different physical and chemical properties. The slurry of the present invention may be composed of a blend of slurries that contain silicas having different physical and chemical properties.

The slurry may be subjected to ion exchange to reduce the concentration of undesirable metals, such as, for example sodium, potassium or iron. Cations or anions may be exchanged. Ion exchange may be accomplished by passing the slurry, following particle size reduction, through a bed of ion-exchange resin. For example sodium or potassium ions are removed by passing the slurry through an acidified cation-exchange resin. Undesired ions may also be removed by metathesis with other ions by exposing the silica, before particle size reduction, as an aqueous slurry with salts of acceptable ions. For example sodium ions may be removed by heating an aqueous precipitated silica slurry with excess potassium chloride. The silica is filtered washed and dried to provide a sodium-reduced silica powder.

In an embodiment, a slurry for use in a CMP process may be formulated by adding a sodium-free acid such as mineral acids, for example sulfuric acid or hydrochloric acid, or organic acids, such as carboxylic acids, diacids, or polyacids, in an amount such that the pH is greater than 2. Various buffers may be used to mitigate pH fluctuations during the CMP process. Other formulation components may also be added to the slurry to optimize performance for a specific CMP application, such as for removal of specific metals. Formulation components may include corrosion inhibitors, static etch controllers, accelerators, metal halides such as fluorides, surfactants, metal chelating or complexing agents, and oxidants.

The slurry of the present invention may also be used for CMP of dielectric materials, such as interlayer dielectrics (ILD) used in microelectronic devices, such as metal oxide semiconductors (MOS), complementary-MOS (CMOS), dynamic random access memory (DRAM), among others. Process methods for manufacturing these devices include damascene, dual damascene, and shallow trench isolation. These ILD may be silicon dioxide, or metal-doped silicon dioxide such as with boron or phosphorus in borophosphate silica glass (BPSG). These silicon dioxide type ILD may be produced by chemical vapor deposition (CVD), or plasma-enhanced CVD, high density Plasma CVD, or thermal oxidation. Other ILD materials include spin-on glasses (SOG) or polymeric materials such as polyimides. These other ILD materials include silicon-based materials such as Black Diamond™, fluorine-doped silicate, xerogels, or silisesquioxanes such as hydrogen silisesquioxanes and organo silisesquioxanes. Carbon-based ILD include for example paralyene, SILK™, amorphous carbon or fluorocarbon, diamond-like carbon or fluorocarbon, or mixtures thereof.

The present invention is more particularly described in the following examples, which are intended to be illustrative only, since numerous modifications and variations therein will be apparent to those skilled in the art. Unless otherwise specified, all parts and all percentages are by weight.

In the following examples, all polishing experiments were performed using a commercially available bench-top polisher model DAP-V™ from Struers The copper and tantalum disks used in these experiments were 3 mm thick, 99.99% pure and had a diameter of 1.25 inches. Unless stated otherwise, the table speed was maintained at 90 rpm, the slurry feed rate was 60 milliliters per minute, and polishing pressure was 6.3 psig. The slurry was continuously stirred in the supply tank using a magnetic stirrer to maintain a good dispersion. The polishing pad used was either a Suba 500 or IC 1400, both of which are available from Rodel. The pad was hand-conditioned for 1 minute using 220 grit sandpaper before every polishing run. The polish rates were determined by measuring the weight of the disk before polishing and after polishing for 3 minutes. The polish rates reported were obtained by averaging the polish rates obtained over 3 to 5 repeated polishing runs.

### EXAMPLES

For each of the examples, an additive silicate solution was prepared by diluting commercially available concentrated aqueous potassium silicate with deionized water to the K₂O concentration that is specified in each example. The concentrated aqueous silicate solution generally was received with a composition of 30 weight percent SiO₂ and a SiO₂:K₂O molar ratio of 3.25. Unless otherwise specified, the acid used in each of these examples was sulfuric acid.

As used in the present specification and claims, the CTAB surface area of the amorphous precipitated silica is the CTAB surface area determined in accordance the following procedure: Using an analytical balance, 11.0 grams (g) of cetyltrimethylammonium bromide, also known as CTAB and as hexadecyltrimethylammonium bromide [CAS 57-09-0], was weighed to the nearest one-tenth milligram and the weight expressed in grams, C, was recorded. The weighed CTAB was dissolved in distilled water and diluted with distilled water to 2 liters in a volumetric flask to form a standard CTAB solution was stored in the dark for at least 12 days before use. Using an analytical balance, 3.70 grams of Aerosol® OT, sodium di(2-ethylhexyl) sulfosuccinate, [CAS 577-11-7] was weighed. The weighed Aerosol® OT was dissolved in distilled water and diluted with distilled water to 2 liters in a volumetric flask to form a standard Aerosol® OT solution which was stored in the dark for at least 12 days before use. The useful storage lives of the standard CTAB solution and the standard Aerosol® OT solution are two months after the 12 day storage period. Using a pipet, 10.0 milliliters (mL) of the CTAB standard solution was transferred to a 250 mL Erlenmeyer flask containing a stirring bar. Next, 30 mL chloroform, 50 mL distilled water, 15 drops of 0.02% bromophenol blue aqueous indicator solution, and one drop of 1N aqueous NaOH solution were added to the flask. With vigorous stirring but minimal splashing, the contents of the Erlenmeyer flask were titrated with the standard Aerosol® OT solution from a 50 mL buret. The titration was begun at a rapid drop rate (the stopcock was never wide open) down to about 25 to 30 mL and then more slowly, dropwise, to the end point which occurred at about 37.5 mL. The approach to the end point was characterized first by a milky blue color throughout. Then, as the end point was more closely approached, the bottom chloroform layer became a more intense blue and the top aqueous layer took on a lilac or purple hue. Immediately before the end point, the vigorously stirred mixture became visibly clearer (i.e., less “milky”), and the bottom layer was seen as a very intense blue.

Using a wash bottle, the inside of the flask was washed down with no more than 25 mL of distilled water. The stirrer speed was increased to resume vigorous mixing for efficient contacting of the two liquid phases. At least 10 seconds were allowed to elapse after each dropwise addition of titrant immediately prior to the endpoint. Stirring was stopped frequently to allow the phases to separate so that the analyst could observe these color changes and then vigorous stirring was resumed. At the end point, the bottom phase lost all color and displayed a colorless or milky white appearance while the top phase was intensely purple. The titrated volume was recorded to the nearest 0.01 mL. The titration of the standard CTAB solution was performed at least two times (the titrant volume must agree within 0.05 mL) and the average volume of standard Aerosol® OT solution used per titration, V₁, was recorded.

A 200 ml wide mouth glass bottle was tared and approximately 0.500 gram of silica sample (in the as-received state, not dried) was placed in the bottle and weighed to the nearest 0.1 mg. This silica sample weight, S, was recorded. One hundred milliliters of the standard CTAB solution was pipetted into the bottle by using a 50 mL pipet, filling and delivering twice; and a stirring bar was carefully added. The mouth of the bottle was covered with aluminum foil, and the contents were stirred gently for 15 minutes without pH adjustment. Using a pH electrode, the pH was adjusted to between 9.0 and 9.5 using 1N aqueous NaOH added dropwise. When the pH had been stabilized between 9.0 and 9.5, the mouth of the bottle was covered again with aluminum foil or equivalent to retard evaporation loss. The mixture was stirred gently for one hour at pH 9.0 to 9.5. The silica-liquid mixture was transferred to centrifuge tubes, and the mixture was centrifuged for 30 minutes to produce a clear centrifugate. Clear centrifugate was carefully withdrawn using a dropping pipet and transferred to a small, dry glass bottle. Using a pipet, 10.0 mL of the centrifugate was transferred into a 250 mL Erlenmeyer flask containing a stirring bar. Next, 30 mL chloroform, 50 mL distilled water, and 15 drops of 0.02% bromophenol blue aqueous indicator solution were added to the flask. The contents of the Erlenmeyer flask were titrated with the standard Aerosol® OT solution from a 50 mL buret using the same procedure and to the same endpoint used in titrating the standard CTAB solution. The volume of standard Aerosol® OT solution used, V₂, was recorded to the nearest 0.01 mL.

A small glass bottle and cap were heated for at least 30 minutes at 105° C. in a vacuum oven. The bottle and cap were then cooled in a desiccator. The bottle and cap were weighed to the nearest 0.1 milligram (mg), as used herein is the tare weight. Approximately one gram of silica sample was added to the bottle, the cap was placed on the bottle, and their combined weight was recorded to the nearest 0.1 mg. The cap was removed and the sample-containing bottle and cap were heated for 30 minutes at 1050C in a vacuum oven. After introducing vacuum, heating was continued for an additional 30 minutes. The bottle and cap were then cooled in a desiccator. The weight of the bottle containing the sample was recorded to the nearest 0.1 mg. The tare weight was subtracted from the weight in grams of the silica before heating, A, and the weight in grams of the silica after heating, B.

The CTAB surface area (dry basis), ACTAB, expressed in m²/g, is calculated according to the formula:

$${A}_{CTAB} = \frac{( {V}_{1} - {V}_{2} ) ( C ) ( A ) ( 28.92 )}{( {V}_{1} ) ( S ) ( B )}$$

Examples for Silica with Low Surface Area and Low Surface Roughness

### Example 1

An initial aqueous potassium silicate solution was prepared by heating water (75 liters) to a temperature of 205° F. (96° C.), and adding an additive aqueous potassium silicate (1.2 liters, 118.8 gm K₂O/liter) The stirred solution was adjusted to a pH of 8.5 by adding concentrated sulfuric acid. After 5 minutes, additive potassium silicate solution (31.7 liters) and concentrated sulfuric acid (2.16 liters) were added simultaneously over a period of 45 minutes. The resulting slurry was stirred at a temperature of 205° F. for an additional 80 minutes. Acid was then added to reduce the pH of the slurry from 8.5 to 4.2. A portion of the product slurry was filtered and washed with water. The resulting filtercake was liquefied by using high shear from a Cawles™ blade on an overhead mixer, and the resulting slurry was adjusted to a pH 6.3. A portion of this slurry was spray dried to produce a white powder having a weight percent moisture of 3.27. Analysis of this powder showed the following properties: Nitrogen BET (5-point) 89 m²/g; CTAB 89 m²/g; 243 ml of dibutyl phthalate per 100 gm of anhydrous powder. From these CTAB data the average primary particle diameter is calculated to be 30 nanometers. The calculated surface roughness is 1.0.

Particle size reduction was conducted using a double-jet cell that contained an elongated chamber of alumina reactors (6 reactors, 1 mm ID) and alternating Ultra-high molecular weight polyethylene (UHMWPE) seals (2.6 mm ID). Water was pressurized (45,000 psig) and passed through two opposing nozzles (0.1 mm ID and 0.13 mm ID) to produce water jets that entered this elongated chamber from opposite directions. A portion of the spray dried powder was introduced into this double-jet cell between the dominant water jet (from the 0.13 mm ID nozzle) and the elongated chamber. The slurry effluent was discharged at atmospheric pressure from this double-jet cell through an opening between the recessive water jet (from the 0.1 mm nozzle) and the elongated chamber. This slurry contained 8.71 weight percent, and the aggregate particle size was characterized by laser light scattering as follows: average 0.219 microns; median 0.181 microns.

A portion of the slurry was diluted with deionized water to 5.4 weight percent solids and formulated for copper and tantalum polishing evaluation with a Struers DAP-V™ and a polishing pad (SUBA 500™) manufactured by Rodel. The formulations and metal removal rates are shown in Table 1 below:

TABLE 1

| | | Copper | Tantalum | |
|---|---|---|---|---|
| | | Removal | Removal | |
| Sample | | Rate | Rate | Copper:Tantalum |
| Chemicals Added | pH | (nm/min) | (nm/min) | Selectivity |
| A1 | 5.5 | 0 | 53 | 0.0 |
| none | | | | |
| B1 | 5.5 | 53 | 45 | 1.2 |
| 5% wt. Hydrogen | | | | |
| peroxide | | | | |
| C1 | 5.5 | 695 | 7 | 99.3 |
| 5% wt. Hydrogen | | | | |
| peroxide | | | | |
| 1% wt. Glycine | | | | |
| D1 | 2.4 | 161 | 49 | 3.2 |
| 0.005 M Ferric | | | | |
| Nitrate | | | | |

### Example 2

A second batch of silica was prepared using the aforementioned procedure in Example 1, with the exception that the amounts of the following reactants were varied. The amount of additive aqueous potassium silicate added to prepare the initial potassium silicate solution was 1.2 liters of 105.7 gm K₂O/liter; and the amount of concentrated sulfuric acid added during the simultaneous addition step was 1.92 liters.

Analysis of the resulting white silica powder showed the following properties: Nitrogen BET (5-point) 108 m²/g; CTAB 91 m²/g; 269 ml of dibutyl phthalate per 100 gm of anhydrous powder. From these CTAB data the average primary particle diameter is calculated to be 30 nanometers. The calculated surface roughness is 1.2.

Particle size reduction was conducted on a portion of the silica using the aforementioned process in Example 1. The resulting slurry was 9.10 weight percent solids, and the aggregate particle size was characterized by laser light scattering as follows: average 0.205 microns; median 0.165 microns; and 10 volume percent greater than 0.401 microns. The volume percent of particles greater than 1.05 microns was 0.

### Example 3

A particle size reduction of a portion of the second batch of silica (Example 2) was conducted by using a conventional homogenizer. A portion of the filtercake was liquefied with high shear and diluted with water to 10 percent solids at pH 4. The particle size for this slurry was characterized by laser light scattering as follows: average 31.53 microns; median 27.06 microns; and 10 volume percent greater than 58.65 microns. The volume percent of particles greater than 1.05 microns was 100. This slurry was pressurized and passed through an APV LAB 1000 Gaulin-type homogenizer that was fitted with a tungsten-carbide valve and seat, with the gap adjusted to provide about 12,500 psig of back-pressure. The aggregate particle size for this slurry was characterized by laser light scattering as follows: average 0.253 microns; median 0.194 microns; and 10 volume percent greater than 0.481 microns. The volume percent of particles greater than 1.05 microns was 0.851.

The single-pass slurry was pressurized and passed through an APV LAB 1000 Gaulin-type homogenizer that was fitted with a tungsten-carbide valve and seat with the gap adjusted to provide about 13,000 psig of back-pressure. This product slurry was 9.24 weight percent solids, and the aggregate particle size was characterized by laser light scattering as follows: average 0.241 microns; median 0.200 microns; and 10 volume percent greater than 0.464 microns. The volume percent of particles greater than 1.05 microns was 0.0.

### Comparative Example 4

A comparison was made using silica slurries of Examples 2 and 3 which represent two particle-size reduction methods (average particle sizes 0.205 and 0.21 microns, respectively). Formulations of 5 weight percent H₂O₂ with 5.4 weight percent silica at a pH of 4.The results are shown in Table 2 below.

TABLE 2

| | | Slurry of | Slurry of | Slurry of | Slurry of |
|---|---|---|---|---|---|
| | | Example 3 | Example 4 | Example 3 | Example 4 |
| | | Copper | Copper | Tantalum | Tantalum |
| | | Removal | Removal | Removal | Removal |
| Pressure | Velocity | Rate | Rate | Rate | Rate |
| psig | RPM | (nm/min) | (nm/min) | (nm/min) | (nm/min) |
| 1.8 | 80 | 25 | 24 | 16 | 17 |
| 1.8 | 100 | 30 | 28 | 20 | 13 |
| 3.9 | 80 | 45 | 27 | 32 | 32 |
| 3.9 | 100 | 41 | 50 | 38 | 34 |
| 6.3 | 80 | 61 | 45 | 58 | 40 |
| 6.3 | 100 | 67 | 66 | 49 | 44 |
| K | | 8.1 | 6.6 | 7.9 | 5.9 |

Velocity has little effect within the narrow range of 80 to 100 RPM that was tested. The effect of pressure can be estimated by the Preston equation:

Equation 1

RR=KP_{V}+C.

Removal rate for a given metal is RR, P_{V} is pressure at a constant velocity, C is RR at zero pressure, and K is the Preston constant which indicates the increase in RR with increasing pressure.

The Preston constant for copper removal rate with slurry of Example 2 is 1.2 times that of Example 3. The Preston constant for tantalum removal rate with slurry of Example 2 is 1.3 times that of Example 3.

This example demonstrates that a slurry composition from the method by which a silica powder is reduced by a single-pass operation through a double-jet cell provides distinct and superior performance when compared to a slurry composition from a conventional homogenization method.

### Example 5

A silica was prepared using the aforementioned procedure in Example 1. Analysis of the resulting white powder showed the following properties: Nitrogen BET (5-point) 97 m²/g; CTAB 99 m²/g; 264 ml of dibutyl phthalate per 100 gm of anhydrous powder. From these data the average primary particle diameter is calculated to be 27 nanometers. The calculated surface roughness is 1.0.

A particle size reduction was conducted by using the process described in Example 1 with the exception that higher silica feed rate relative to the water feed rate was used. The resulting slurry was 22.22 weight percent solids. The aggregate particle size was characterized by laser light scattering as follows: average 0.216 microns; median 0.174 microns; and 10 volume percent greater than 0.420 microns.

### Example 6

A silica was prepared using the produce described in Example 1. Analysis of the resulting white powder showed the following properties: Nitrogen BET (5-point) 89 m²/g; CTAB 91 m²/g; 244 ml of dibutyl phthalate per 100 gm of anhydrous powder, X-ray Fluorescence Chloride32 ppm, X-ray Fluorescence sulfate 0.095 weight percent as sodium sulfate, Loss on ignition (1150° C.) 6.07 weight percent, moisture (105° C.) 3.62 weight percent. From these CTAB data the average primary particle diameter is calculated to be 30 nanometers. From bound water determination of 2.39 weight percent, the hydroxyl content was calculated to be 18 hydroxyls per nanometer squared. The calculated surface roughness is 1.0.

Particle size reduction was conducted by using the aforementioned process described in Example 1. This slurry (813-973) was 6.67 weight percent solids, and the aggregate particle size was characterized by laser light scattering as follows: average 0.215 microns; median 0.175 microns; and 10 volume percent greater than 0.416 microns.

### Example 7

An initial aqueous potassium silicate solution was prepared by heating water (110 gallons) and additive aqueous potassium silicate (1.6 gallons; 111.2 gm K₂O/liter). This stirred solution was neutralized to pH 8.5, and heated to 205° F. After 5 min, additive potassium silicate solution (41.9 gallons) and concentrated sulfuric acid (10.4 liters) were added simultaneously over a period of 45 minutes. The resulting slurry was allowed to stir at 205° F. for an additional 80 minutes at pH 8.5, then was acidified to pH 4.2. A portion of the product slurry was filtered, and water washed. The resulting filter cake was liquefied by high shear, and adjusted to pH 6.3. A portion of this slurry was spray dried to produce a white powder with a nominal average particle size by laser light scattering of 30 microns and 10 volume percent greater than 50 microns (813-1121, 2.95 percent moisture). Analysis of this powder showed the following properties: Nitrogen BET (5-point) 92 m²/g; CTAB 93 m²/g; 259 ml of dibutyl phthalate per 100 gm of anhydrous powder. From these data the average primary particle diameter is calculated to be 29 nanometers. The calculated surface roughness is 1.0.

Particle size reduction was conducted by using a double-jet cell that contained an elongated chamber of alumina reactors (6 reactors, 1 mm ID) and alternating UHMWPE seals (2.6 mm ID). Water was pressurized (45,000 psig) and passed through two nozzles (0.1 mm ID and 0.13 mm ID) to produce water jets that entered this elongated chamber from opposite directions. A portion of spray dried powder (813-1121) was introduced into this double-jet cell between the dominant water jet (from the 0.13 mm ID nozzle) and the elongated chamber. The slurry effluent was discharged at atmospheric pressure from this double-jet cell through an opening between the recessive water jet (from the 0.1 mm nozzle) and the elongated chamber. This slurry (813-1180, 15.3 kg) was 13.33 weight percent solids, and the aggregate particle size was characterized by laser light scattering as follows: average 0.164 microns; median 0.126 microns; and 10 volume percent greater than 0.331 microns.

A portion of the slurry (813-1180) was diluted with deionized water, and formulated for copper and tantalum polishing evaluation with a Struers DAP-V and an IC1400% pad (Rodel). Metal removal rates were measured with varying polishing pressure, pad velocity, and abrasive concentrations and using formulation of 5 weight percent hydrogen peroxide at pH 4. The results were as follows:

TABLE 3

| | | | Copper | Tantalum |
|---|---|---|---|---|
| Silica | | | Removal | Removal |
| concentration | Pressure | Velocity | Rate | Rate |
| Wt % | psig | RPM | (nm/min) | (nm/min) |
| 5.4 | 1.8 | 80 | 25 | 18 |
| 5.4 | 1.8 | 100 | 28 | 15 |
| 5.4 | 6.3 | 80 | 46 | 49 |
| 5.4 | 6.3 | 100 | 49 | 47 |
| 1.0 | 1.8 | 80 | 20 | 3 |
| 1.0 | 1.8 | 100 | 23 | 6 |
| 1.0 | 6.3 | 80 | 27 | 12 |
| 1.0 | 6.3 | 100 | 34 | 14 |

Another portion of spray dried powder (813-1121) was introduced into this double-jet cell between the dominant water jet (from the 0.13 mm ID nozzle) and the elongated chamber. The slurry effluent was discharged at atmospheric pressure from this double-jet cell through an opening between the recessive water jet (from the 0.1 mm nozzle) and the elongated chamber. This slurry (813-1192, 17.8 kg) was 12.29 weight percent solids, and the aggregate particle size was characterized by laser light scattering as follows: average 0.166 microns; median 0.126 microns; and 10 volume percent greater than 0.341 microns.

Another portion of spray dried powder (813-1121) was introduced into this double-jet cell between the dominant water jet (from the 0.13 mm ID nozzle) and the elongated chamber. The slurry effluent was discharged at atmospheric pressure from this double-jet cell through an opening between the recessive water jet (from the 0.1 mm nozzle) and the elongated chamber. This slurry (813-1235, 22.5 kg) was 16.41 weight percent solids, and the aggregate particle size was characterized by laser light scattering as follows: average 0.160 microns; median 0.127 microns; and 10 volume percent greater than 0.309 microns This slurry (813-1235) was filtered by pumping through the following filters in series: 75 micron/25 micron gradient cartridge, 25 micron/i micron gradient cartridge, Millipore CM13 cartridge, and Millipore CMP 5 cartridge. An air-driven diaphragm pump was used to pump the slurry. The increase in pressure drop across the filters was negligible over the course of the filtration. The product slurry (813-1247, 9.90 kilograms) was 14.30 weight percent solids and the aggregate particle size was characterized by laser light scattering as follows: average 0.131 microns; median 0.118 microns; and 10 volume percent greater than 0.218 microns.

This slurry was then prepared for Flame Atomic Emission Spectroscopy by digesting the silica with hydrofluoric acid and sulfuric acid, followed by digestion with nitric acid and sulfuric acid. After evaporation to fumes of sulfuric acid, the dissolution was completed in hydrochloric acid. Samples were diluted to volume, shaken, and analyzed via Flame Emission Spectroscopy. Analysis of this slurry showed 0.062 weight percent potassium and 2.5 ppm sodium. This slurry (pH 6.9) was then pumped through a strong acid cation column for ion exchange. The column was 1 inch in diameter by 30 inches tall and contained approximately 19.75 inches of Bayer KPS macro reticulate ion exchange resin. The column had been regenerated with sulfuric acid (0.713 L@ 40 g/L). The slurry was fed at approximately 0.5 GPM/ft³ bed volume, and the effluent product was collected. This slurry (813-1263, pH 2.4) was then prepared for Flame Atomic Emission Spectroscopy as previously described. Analysis of this slurry by Flame Emission Spectroscopy showed 0.039 weight percent potassium and 16 ppm sodium.

Examples of Silica with Low Surface Area and High Surface Roughness

### Example 8

An initial aqueous potassium silicate solution was prepared by heating water (75 liters) was heated to 205° F., and additive aqueous potassium silicate (1.2 liters, 105.7 gm K₂O/liter) was added. This stirred solution was neutralized to pH 8.5. After 5 minutes, additive potassium silicate solution (31.7 liters) and concentrated sulfuric acid (1.92 liters) were added simultaneously over a period of 45 minutes. Aqueous potassium hydroxide (45 weight percent, 3000g) was added. The resulting slurry was allowed to stir at 205° F. for an additional 80 minutes, then was acidified to pH 4.2. A portion of the product slurry was filtered, and water washed. The resulting filter cake (810-727) was liquefied by high shear, and adjusted to pH 6.3. A portion of this slurry was spray dried to produce a white powder with a nominal average particle size by laser light scattering of 30 microns and 10 volume percent greater than 50 microns (810-728, 6.04 percent moisture). Analysis of this powder showed the following properties: Nitrogen BET (5-point) 141 m²/g; CTAB 72 m²/g; 264 ml of dibutyl phthalate per 100 gm of anhydrous powder. From these data the average primary particle diameter is calculated to be 38 nanometers. The calculated surface roughness is 2.0.

Particle size reduction was conducted by using a double-jet cell that contained an elongated chamber of alumina reactors (6 reactors, 1 mm ID) and alternating UHMWPE seals (2.6 mm ID). Water was pressurized (45,000 psig) and passed through two nozzles (0.1 mm ID and 0.13 mm ID) to produce water jets that entered this elongated chamber from opposite directions. A portion of spray dried powder (810-728) was introduced into this double-jet cell between the dominant water jet (from the 0.13 mm ID nozzle) and the elongated chamber. The slurry effluent was discharged at atmospheric pressure from this double-jet cell through an opening between the recessive water jet (from the 0.1 mm nozzle) and the elongated chamber. This slurry (813-906) was 10.20 weight percent solids, and the aggregate particle size was characterized by laser light scattering as follows: average 0.210 microns; median 0.167 microns; and 10 volume percent greater than 0.415 microns.

A portion of the slurry (813-906) was diluted to 5.4 weight percent solids with deionized water, and formulated for copper and tantalum polishing evaluation with a Struers DAP-V and a SUBA 500™ pad (Rodel). The formulations and metal removal rates are as follows:

TABLE 4

| | | Copper | Tantalum | |
|---|---|---|---|---|
| | | Removal | Removal | |
| | | Rate | Rate | Copper:Tantalum |
| Formulation | pH | (nm/min) | (nm/min) | Selectivity |
| Water only | 4.9 | 3 | 55 | 0.1 |
| 5% wt. Hydrogen | 4.7 | 78 | 39 | 2.0 |
| peroxide | | | | |
| 5% wt. Hydrogen | 5.3 | 714 | 8 | 89.3 |
| peroxide | | | | |
| 1% wt. Glycine | | | | |
| 0.005 M Ferric | 2.4 | 144 | 51 | 2.8 |
| Nitrate | | | | |

### Example 9

A particle size reduction of a portion of the previous example batch of silica (Example 8) was conducted by using a conventional homogenizer. A portion of the filter cake was liquefied with high shear and diluted with water to 10 percent solids at pH 4. The particle size for this slurry (813-921) was characterized by laser light scattering as follows: average 26.58 microns; median 22.87 microns; and 10 volume percent greater than 48.76 microns. The volume percent of particles greater than 1.05 microns was 100. This slurry (813-921) was pressurized and passed through an APV LAB 1000 Gaulin-type homogenizer that was fitted with a tungsten-carbide valve and seat with the gap adjusted to provide about 12,600 psig of back-pressure. The particle size for this product slurry (813-922), was characterized by laser light scattering as follows: average 0.441 microns; median 0.201 microns; and 10 volume percent greater than 0.686 microns. The volume percent of particles greater than 1.05 microns was 9.6.

A second pass through a conventional homogenizer was required to reduce all the particles to less than 1 micron. The single-pass slurry (813-922) was pressurized and passed through an APV LAB 1000 Gaulin-type homogenizer that was fitted with a tungsten-carbide valve and seat with the gap adjusted to provide about 13,000 psig of back-pressure. This product slurry (813-925) was 10.21 weight percent solids, and the aggregate particle size was characterized by laser light scattering as follows: average 0.229 microns; median 0.180 microns; and 10 volume percent greater than 0.455 microns. The volume percent of particles greater than 1.05 microns was 0.0.

### Comparative Example 10

A comparison was made using silica slurries of Examples 8 and 9 which represent two particle-size reduction methods (average particle sizes 0.210 microns and 0.229 microns respectively). Formulations of 5 weight percent H₂O₂ with 5.4 weight percent silica at a pH of 4.The results are shown in Table 5 below.

TABLE 5

| | | Example 8 | Example 9 | Example 8 | Example 9 |
|---|---|---|---|---|---|
| | | Copper | Copper | Tantalum | Tantalum |
| | | Removal | Removal | Removal | Removal |
| Pressure | Velocity | Rate | Rate | Rate | Rate |
| psig | RPM | (nm/min) | (nm/min) | (nm/min) | (nm/min) |
| 1.8 | 80 | 42 | 30 | 14 | 12 |
| 1.8 | 100 | 42 | 35 | 19 | 12 |
| 3.9 | 80 | 68 | 43 | 40 | 29 |
| 3.9 | 100 | 60 | 47 | 40 | 26 |
| 6.3 | 80 | 95 | 56 | 58 | 30 |
| 6.3 | 100 | 92 | 62 | 50 | 39 |
| K | | 11.5 | 5.9 | 8.3 | 5.0 |

Velocity has little effect within the narrow range of 80 to 100 RPM that was tested. The effect of pressure can be estimated by the Preston equation, Equation 1. The Preston constant, K, indicates the increase in RR with increasing pressure. The Preston constant for copper removal rate with Example 8 is 1.9 times that of Example 9. The Preston constant for tantalum removal rate with Example 8 is 1.7 times that of Example 9.

This example demonstrates that a slurry composition from the method by which a silica powder is reduced by a single-pass operation through a double-jet cell provides distinct and superior performance when compared to a slurry composition from a conventional homogenization method.

### Example 11

A second batch of silica was prepared using the aforementioned procedure in Example 8 with the exception that the amounts of the following reactants were varied. An initial aqueous potassium silicate solution was with additive aqueous potassium silicate (1.2 liters, 110.5 gm K₂O/liter) was added. This stirred solution was neutralized to pH 8.5. After 5 minutes, additive potassium silicate solution (31.7 liters) and concentrated sulfuric acid (2.03 liters) were added simultaneously over a period of 45 minutes. Analysis of spray-dried powder product showed the following properties: 6.01 weight percent moisture, Nitrogen BET (5-point) 140 m²/g; CTAB 83 m²/g; 270 ml of dibutyl phthalate per 100 gm of anhydrous powder. From these data the average primary particle diameter is calculated to be 33 nanometers. From bound water determination, the hydroxyl content was calculated to be 29 hydroxyls per nanometer squared. The calculated surface roughness is 1.7.

Particle size reduction was conducted by using a double-jet cell that contained an elongated chamber of alumina reactors (6 reactors, 1 mm ID) and alternating UHMWPE seals (2.6 mm ID). Water was pressurized (45,000 psig) and passed through two nozzles (0.1 mm ID and 0.13 mm ID) to produce water jets that entered this elongated chamber from opposite directions. A portion of spray dried powder (810-854) was introduced into this double-jet cell between the dominant water jet (from the 0.13 mm ID nozzle) and the elongated chamber. The slurry effluent was discharged at atmospheric pressure from this double-jet cell through an opening between the recessive water jet (from the 0.1 mm nozzle) and the elongated chamber. This slurry (813-1081) was 12.00 weight percent solids, and the aggregate particle size was characterized by laser light scattering as follows: average 0.209 microns; median 0.169 microns; and 10 volume percent greater than 0.407 microns.

Examples for Silica with High Surface Area and Low Surface Roughness

### Example 12

An initial aqueous potassium silicate solution was prepared by heating water (75 liters) was heated to 167° F., and additive aqueous potassium silicate (2.39 liters, 113 gm K₂O/liter) was added. After 5 minutes, additive potassium silicate solution (31.5 liters) and concentrated sulfuric acid (1.96 liters) were added simultaneously over a period of 90 minutes. The resulting slurry was allowed to stir at 205° F. for an additional 30 minutes, then was acidified to pH 4.2. A portion of the product slurry was filtered, and water washed. The resulting filter cake was liquefied by high shear, adjusted to pH 6.3, and a portion of this slurry was spray dried to produce a white powder (810-881, 4.06 percent moisture). Analysis of this powder showed the following properties: Nitrogen BET (5-point) 166 m²/g; CTAB 156 m²/g; 293 ml of dibutyl phthalate per 100 gm of anhydrous powder. From these data the average primary particle diameter is calculated to be 17 nanometers. From bound water determination, the hydroxyl content was calculated to be 12 hydroxyls per nanometer squared. The calculated surface roughness is 1.1.

Particle size reduction was conducted by using a double-jet cell that contained an elongated chamber of alumina reactors (6 reactors, 1 mm ID) and alternating UHMWPE seals (2.6 mm ID). Water was pressurized (45,000 psig) and passed through two nozzles (0.1 mm ID and 0.13 mm ID) to produce water jets that entered this elongated chamber from opposite directions. A portion of spray dried powder (810-881) was introduced into this double-jet cell between the dominant water jet (from the 0.13 mm ID nozzle) and the elongated chamber. The slurry effluent was discharged at atmospheric pressure from this double-jet cell through an opening between the recessive water jet (from the 0.1 mm nozzle) and the elongated chamber. This slurry (813-1106) was 8.59 weight percent solids, and the aggregate particle size was characterized by laser light scattering as follows: average 0.207 microns; median 0.165 microns; and 10 volume percent greater than 0.406 microns.

### Example 13

A silica was prepared using the aforementioned procedure in Example 12. Analysis of the spray dried powder product showed the following properties: 4.92 weight percent moisture Nitrogen BET (5-point) 158 m²/g; CTAB 152 m²/g; 299 ml of dibutyl phthalate per 100 gm of anhydrous powder. From these data the average primary particle diameter is calculated to be 18 nanometers. The calculated surface roughness is 1.0. Particle size reduction was conducted by using a double-jet cell that contained an elongated chamber of alumina reactors (6 reactors, 1 mm ID) and alternating UHMWPE seals (2.6 mm ID). Water was pressurized (45,000 psig) and passed through two nozzles (0.1 mm ID and 0.13 mm ID) to produce water jets that entered this elongated chamber from opposite directions. A portion of spray dried powder (810-903) was introduced into this double-jet cell between the dominant water jet (from the 0.13 mm ID nozzle) and the elongated chamber. The slurry effluent was discharged at atmospheric pressure from this double-jet cell through an opening between the recessive water jet (from the 0.1 mm nozzle) and the elongated chamber. This slurry (813-1186) was 12.86 weight percent solids, and the aggregate particle size was characterized by laser light scattering as follows: average 0.207 microns; median 0.166 microns; and 10 volume percent greater than 0.406 microns.

A portion of the slurry (813-1186) was diluted with deionized water, and formulated for copper and tantalum polishing evaluation with a Struers DAP-V and an IC140OTM pad (Rodel). Metal removal rates were measured with varying polishing pressure, pad velocity, and abrasive concentrations and using formulation of 5 weight percent hydrogen peroxide at pH 4. The results were as follows:

TABLE 6

| | | | Copper | Tantalum |
|---|---|---|---|---|
| Silica | | | Removal | Removal |
| concentration | Pressure | Velocity | Rate | Rate |
| Wt % | psig | RPM | (nm/min) | (nm/min) |
| 3.0 | 1.8 | 80 | 18 | 9 |
| 3.0 | 1.8 | 100 | 24 | 8 |
| 3.0 | 6.3 | 80 | 25 | 28 |
| 3.0 | 6.3 | 100 | 31 | 24 |
| 6.0 | 1.8 | 80 | 25 | 16 |
| 6.0 | 1.8 | 100 | 26 | 16 |
| 6.0 | 6.3 | 80 | 41 | 40 |
| 6.0 | 6.3 | 100 | 41 | 42 |

Example for Fumed Silica with Low Surface Area and Low Surface Roughness

### Example 14

A commercially available sample of fumed silica Cabot L90 was obtained. Analysis of this powder (813-1179; 0.66 weight percent moisture) showed the following properties: Nitrogen BET (5-point) 93 m²/g; CTAB 100 m²/g; and particle size characterized by laser light scattering as follows: average 0.188 microns; median 0.145 microns; and 10 volume percent greater than 0.382 microns. From these data the average primary particle diameter is calculated to be 27 nanometers. The calculated surface roughness is 0.9.

Particle size reduction was conducted by using a double-jet cell that contained an elongated chamber of alumina reactors (6 reactors, 1 mm ID) and alternating UHMWPE seals (2.6 mm ID). Water was pressurized (45,000 psig) and passed through two nozzles (0.1 mm ID and 0.13 mm ID) to produce water jets that entered this elongated chamber from opposite directions. A portion of powder (813-1179) was introduced into this double-jet cell between the dominant water jet (from the 0.13 mm ID nozzle) and the elongated chamber. The slurry effluent was discharged at atmospheric pressure from this double-jet cell through an opening between the recessive water jet (from the 0.1 mm nozzle) and the elongated chamber. This slurry (813-1188) was 11.56 weight percent solids, and the aggregate particle size was characterized by laser light scattering as follows: average 0.111 microns; median 0.099 microns; and 10 volume percent greater than 0.178 microns.

A portion of the slurry (813-1188) was diluted with deionized water, and formulated for copper and tantalum polishing evaluation with a Struers DAP-V and an IC1400™ pad (Rodel) Metal removal rates were measured with varying polishing pressure, pad velocity, and abrasive concentrations and using formulation of 5 weight percent hydrogen peroxide at pH 4. The results were as follows:

TABLE 7

| | | | Copper | Tantalum |
|---|---|---|---|---|
| Silica | | | Removal | Removal |
| concentration | Pressure | Velocity | Rate | Rate |
| Wt % | psig | RPM | (nm/min) | (nm/min) |
| 5.4 | 1.8 | 80 | 41 | 8 |
| 5.4 | 1.8 | 100 | 54 | 11 |
| 5.4 | 6.3 | 80 | 66 | 20 |
| 5.4 | 6.3 | 100 | 82 | 25 |
| 1.0 | 1.8 | 80 | 32 | 3 |
| 1.0 | 1.8 | 100 | 40 | 4 |
| 1.0 | 6.3 | 80 | 48 | 10 |
| 1.0 | 6.3 | 100 | 60 | 14 |

Examples for Fumed Silica with High Surface Area and Low Surface Roughness

### Example 15

A commercially available sample of fumed silica Aerosil 130 was obtained. Analysis of this powder (813-1003; 1.25 weight percent moisture) showed the following properties: Nitrogen BET (5-point) 137 m²/g; CTAB 142 m²/g; 218 ml of dibutyl phthalate per 100 gm of anhydrous powder. The aggregate particle size was characterized by laser light scattering as follows: average 31.06 microns; median 23.99 microns; and 10 volume percent greater than 62.47 microns. From these data the average primary particle diameter is calculated to be 19 nanometers. The calculated surface roughness is 1.0.

Particle size reduction was conducted by using a double-jet cell that contained an elongated chamber of alumina reactors (6 reactors, 1 mm ID) and alternating UHMWPE seals (2.6 mm ID). Water was pressurized (45,000 psig) and passed through two nozzles (0.1 mm ID and 0.13 mm ID) to produce water jets that entered this elongated chamber from opposite directions. A portion of powder (813-1003) was introduced into this double-jet cell between the dominant water jet (from the 0.13 mm ID nozzle) and the elongated chamber. The slurry effluent was discharged at atmospheric pressure from this double-jet cell through an opening between the recessive water jet (from the 0.1 mm nozzle) and the elongated chamber. This slurry (813-1190) was 9.86 weight percent solids, and the aggregate particle size was characterized by laser light scattering as follows: average 0.106 microns; median 0.096 microns; and 10 volume percent greater than 0.169 microns.

A portion of the slurry (813-1190) was diluted with deionized water, and formulated for copper and tantalum polishing evaluation with a Struers DAP-V and an IC140o™ pad (Rodel). Metal removal rates were measured with varying polishing pressure, pad velocity, and abrasive concentrations and using formulation of 5 weight percent hydrogen peroxide at pH 4. The results were as follows:

TABLE 8

| | | | Copper | Tantalum |
|---|---|---|---|---|
| Silica | | | Removal | Removal |
| concentration | Pressure | Velocity | Rate | Rate |
| Wt % | psig | RPM | (nm/min) | (nm/min) |
| 3.0 | 1.8 | 80 | 25 | 8 |
| 3.0 | 1.8 | 100 | 28 | 9 |
| 3.0 | 6.3 | 80 | 36 | 38 |
| 3.0 | 6.3 | 100 | 39 | 33 |
| 6.0 | 1.8 | 80 | 28 | 12 |
| 6.0 | 1.8 | 100 | 32 | 21 |
| 6.0 | 6.3 | 80 | 42 | 41 |
| 6.0 | 6.3 | 100 | 54 | 56 |

### Comparative Example 16

These comparative examples show the difference between silica of the present invention and that prepared from fumed silica with a similar aggregate and primary particle sizes. Data from Tables 5 and 6 were used to represent high and low surface area of silica of the present invention. Data from Tables 7 and 8 were used to represent high and low surface area of fumed silica.

A linear model was used to describe the polishing data obtained with the 5 weight percent hydrogen peroxide formulations at pH 4. A linear regression analysis was performed to solve the for the equation:

Equation 2

MRR=KP_{V}+m[SiO2]+nP_{V}[SiO2]+rS+B.

Where terms are defined as,

Pv is pressure at constant velocity

[SiO2] is weight percent silica abrasive

S is CTAB surface area of the silica abrasive

B is a constant

Velocity had little effect within the narrow range that was employed to obtain these data. Both copper and tantalum removal rates were compared.

In order to make a direct comparison between fumed silica and the current invention, the parameters were compared to orthogonal coded variables, as is accordance with standard statistical methods. This method allows the leverage of each parameter to be compared without the bias of the size of its natural range. Consequently, the leverage of surface area and concentration, for instance, can be compared despite surface area varying over about 50 units, and concentration over only 5 units. The orthogonal coded terms were as follows:

TABLE 9

| Parameter Estimate for | Silica of the | Fumed Silica |
|---|---|---|
| Copper Removal Rate | Present Invention | [Examples 14 |
| (nm/mm) | [Example 8 and 13] | and 15] |
| K | 6.5 | 9.3 |
| m | 4.1 | 2.9 |
| n | 2.2 | 1.2 |
| r | −2.0 | −10.3 |

These parameters show that copper removal rate declines as surface area increases, but the decline is sharper with fumed silica. Increasing silica concentration more strongly impacts copper removal rate for precipitated silica. Increasing pressure raises copper removal rate more sharply for fumed silica.

TABLE 10

| Parameter Estimate for | Silica of the | Fumed Silica |
|---|---|---|
| Tantalum Removal Rate | Present invention | [Examples 14 |
| (nm/mm) | [Example 8 and 13] | and 15] |
| K | 10.4 | 10.1 |
| m | 9.0 | 6.8 |
| n | 4.1 | 2.6 |
| r | −1.9 | 5.6 |

These parameters show that tantalum removal rate declines as surface area increases for precipitated silica, but the rises with fumed silica. Increasing silica concentration more strongly impacts tantalum removal rate for precipitated silica. Increasing pressure raises tantalum removal rate more similarly for both silica types.

This model may be used to estimate predicted removal rates that may further serve to demonstrate the differences between these examples. A model slurry which may be used for this estimate is comprised of 5 weight percent hydrogen peroxide at pH 4 with 4 weight percent silica with surface area of 90 m²/g and polishing pressure of 6 psig and velocity around 90 RPM. The predicted removal rates were as follows:

TABLE 11

| | Copper | Tantalum | Tantalum: |
|---|---|---|---|
| | Removal | Removal | Copper |
| | Rate | Rate | selec- |
| | (nm/min) | (nm/min) | tivity |
| Silica of the Present | 52 | 55 | 1.1 |
| Invention | | | |
| Fumed Silica | 77 | 27 | 0.3 |

This model predicts that low surface precipitated silica will produce higher removal rates for tantalum over copper, and thereby should produce less dishing in the barrier removal CMP step on copper interconnects that use a tantalum barrier. At higher silica surface area, tantalum:copper selectivity changes little for precipitated silica, and remains less than one for fumed silica.

Examples for Silica with High Surface Area and High Surface Roughness

### Example 17

An initial aqueous potassium silicate solution was prepared by heating water (74 liters) was heated to 176° F., and additive aqueous potassium silicate (2.4 liters, 111.2 gm K₂O/liter) was added. Aqueous potassium hydroxide (45 weight percent, 1.4 kg) was added to this hot silicate solution. After 5 minutes, additive potassium silicate solution (31.5 liters) and concentrated sulfuric acid (2 liters) were added simultaneously over a period of 90 minutes. The slurry pH was adjusted to 8.5. The resulting slurry was allowed to stir at 176° F. for an additional 30 minutes, then was acidified to pH 4.2. A portion of the product slurry was filtered, and water washed. The resulting filter cake was liquefied by high shear, adjusted to pH 6.3, and a portion of this slurry was spray dried to produce a white powder (810-980, 6.7 percent moisture). Analysis of this powder showed the following properties: Nitrogen BET (5-point) 237 m²/g; CTAB 107 m²/g; 267 ml of dibutyl phthalate per 100 gm of anhydrous powder. From these data the average primary particle diameter is calculated to be 25 nanometers. The calculated surface roughness is 2.2.

Particle size reduction was conducted by using a double-jet cell that contained an elongated chamber of alumina reactors (6 reactors, 1 mm ID) and alternating UHMWPE seals (2.6 mm ID). Water was pressurized (45,000 psig) and passed through two nozzles (0.1 mm ID and 0.13 mm ID) to produce water jets that entered this elongated chamber from opposite directions. A portion of spray dried powder (810-980) was introduced into this double-jet cell between the dominant water jet (from the 0.13 mm ID nozzle) and the elongated chamber. The slurry effluent was discharged at atmospheric pressure from this double-jet cell through an opening between the recessive water jet (from the 0.1 mm nozzle) and the elongated chamber. This slurry (813-1237) was 14.33 weight percent solids, and the aggregate particle size was characterized by laser light scattering as follows: average 0.206 microns; median 0.166 microns; and 10 volume percent greater than 0.401 microns.

### Example 18

An initial aqueous potassium silicate solution was prepared by heating water (74.5 liters) was heated to 176° F., and additive aqueous potassium silicate (2.4 liters, 111.2 gm K₂O/liter) was added. Aqueous potassium hydroxide (45 weight percent, 0.7 kg) was added to this hot silicate solution. After 5 minutes, additive potassium silicate solution (31.5 liters) and concentrated sulfuric acid (2 liters) were added simultaneously over a period of 90 minutes. The slurry pH was adjusted to 8.5. The resulting slurry was allowed to stir at 176° F. for an additional 30 minutes, then was acidified to pH 4.2. A portion of the product slurry was filtered, and water washed. The resulting filter cake was liquefied by high shear, adjusted to pH 6.3, and a portion of this slurry was spray dried to produce a white powder (6.92 percent moisture). Analysis of this powder showed the following properties: Nitrogen BET (5-point) 218 m²/g; CTAB 134 m²/g; 283 ml of dibutyl phthalate per 100 gm of anhydrous powder. From these data the average primary particle diameter is calculated to be 20 nanometers. The calculated surface roughness is 1.6.

Particle size reduction was conducted by using a double-jet cell that contained an elongated chamber of alumina reactors (6 reactors, 1 mm ID) and alternating UHMWPE seals (2.6 mm ID). Water was pressurized (45,000 psig) and passed through two nozzles (0.1 mm ID and 0.13 mm ID) to produce water jets that entered this elongated chamber from opposite directions. A portion of spray dried powder (810-985) was introduced into this double-jet cell between the dominant water jet (from the 0.13 mm ID nozzle) and the elongated chamber. The slurry effluent was discharged at atmospheric pressure from this double-jet cell through an opening between the recessive water jet (from the 0.1 mm nozzle) and the elongated chamber. This slurry was (813-1238) 11.02 weight percent solids, and the aggregate particle size was characterized by laser light scattering as follows: average 0.158 microns; median 0.132 microns; and 10 volume percent greater than 0.275 microns.

### Example 19

An initial aqueous potassium silicate solution was prepared by heating water (80.5 liters) was heated to 176° F., and additive aqueous potassium silicate (4.8 liters, 111.2 gm K₂O/liter) was added. After 5 minutes, additive potassium silicate solution (31.5 liters) and concentrated sulfuric acid (2 liters) were added simultaneously over a period of 90 minutes. The slurry pH was adjusted to 8.5. The resulting slurry was allowed to stir at 176° F. for an additional 30 minutes, then was acidified to pH 4.2. A portion of the product slurry was filtered, and water washed. The resulting filter cake was liquefied by high shear, adjusted to pH 6.3, and a portion of this slurry was spray dried to produce a white powder (810-987), 7.03 percent moisture). Analysis of this powder showed the following properties: Nitrogen BET (5-point) 217 m²/g; CTAB 147 m²/g; 285 ml of dibutyl phthalate per 100 gm of anhydrous powder. From these data the average primary particle diameter is calculated to be 18.5 nanometers. The calculated surface roughness is 1.5.

Particle size reduction was conducted by using a double-jet cell that contained an elongated chamber of alumina reactors (6 reactors, 1 mm ID) and alternating UHMWPE seals (2.6 mm ID). Water was pressurized (45,000 psig) and passed through two nozzles (0.1 mm ID and 0.13 mm ID) to produce water jets that entered this elongated chamber from opposite directions. A portion of spray dried powder (810-987) was introduced into this double-jet cell between the dominant water jet (from the 0.13 mm ID nozzle) and the elongated chamber. The slurry effluent was discharged at atmospheric pressure from this double-jet cell through an opening between the recessive water jet (from the 0.1 mm nozzle) and the elongated chamber. This slurry (813-1239) was 10.02 weight percent solids, and the aggregate particle size was characterized by laser light scattering as follows: average 0.125 microns; median 0.111 microns; and 10 volume percent greater than 0.213 microns.

### Example 20

An initial aqueous potassium silicate solution was prepared by heating water (86 liters) was heated to 176° F., and additive aqueous potassium silicate (7.2 liters, 111.2 gm K₂O/liter) was added. After 5 minutes, additive potassium silicate solution (31.5 liters) and concentrated sulfuric acid (2 liters) were added simultaneously over a period of 90 minutes. The slurry pH was adjusted to 8.5. The resulting slurry was allowed to stir at 176° F. for an additional 30 minutes, then was acidified to pH 4.2. A portion of the product slurry was filtered, and water washed. The resulting filter cake was liquefied by high shear, adjusted to pH 6.3, and a portion of this slurry was spray dried to produce a white powder (810-989), 7.35 percent moisture). Analysis of this powder showed the following properties: Nitrogen BET (5-point) 244 m²/g; CTAB 129 m²/g; 292 ml of dibutyl phthalate per 100 gm of anhydrous powder. From these data the average primary particle diameter is calculated to be 21 nanometers. The calculated surface roughness is 1.9.

Particle size reduction was conducted by using a double-jet cell that contained an elongated chamber of alumina reactors (6 reactors, 1 mm ID) and alternating UHMWPE seals (2.6 mm ID). Water was pressurized (45,000 psig) and passed through two nozzles (0.1 mm ID and 0.13 mm ID) to produce water jets that entered this elongated chamber from opposite directions. A portion of spray dried powder (810-989) was introduced into this double-jet cell between the dominant water jet (from the 0.13 mm ID nozzle) and the elongated chamber. The slurry effluent was discharged at atmospheric pressure from this double-jet cell through an opening between the recessive water jet (from the 0.1 mm nozzle) and the elongated chamber. This slurry (813-1240) was 11.96 weight percent solids, and the aggregate particle size was characterized by laser light scattering as follows: average 0.137 microns; median 0.115 microns; and 10 volume percent greater than 0.232 microns

Comparative Examples for Silica Slurry Feed Through Single Alumina Orifice

These examples demonstrate that the slurry composition from the method by which silica slurry is fed through an alumina orifice at varying pressures provides a slurry having a particle size distribution characteristic of CMP slurries—i.e. having a completely sub-micron particle size distribution. However, the abrasive slurry quickly wears the alumina nozzle sufficiently such that suitable process intensity cannot be maintained for more than a few small samples

### Example 21

A filter cake (813-368) of a silica of the present invention was liquefied under low shear with water to approximately 12 weight percent to provide silica slurry (813-442) with a pH of approximately 6.3. A portion of this silica slurry when spray dried produced a white powder (813-369). Analysis of this powder showed the following properties: Nitrogen BET (5 point) 158 m²/g; CTAB 152 m²/g. From these data the average primary particle diameter is calculated to be 18 nanometers. The calculated surface roughness is 1.0.

Another portion of this liquefied filiter cake (813-442), having an average particle size of 25.83 microns and a median particle size of 24.180 microns, with 10 volume percent greater then 45.09 microns, was fed through a 0.1 mm I.D. alumina nozzle at different pressure drops across the nozzle. After passing through the nozzle orifice, the fluid then passed into an elongated chamber containing reactors and seals, namely 11 alumina reactors with an internal diameter of 1.0 mm with alternating UHMWPE seals having an internal diameter of 2.6 mm, to the end of the interaction chamber where the stream then reversed and flowed back through the interaction chamber, against the path of the original jet. The outlet port of the interaction chamber was directed to a stainless steel coil immersed in a bath of ice and water, and the product slurry was collected in an open container.

At a pressure drop across the orifice of 15,000 psig, the slurry effluent comprising of approximately 150 ml (813-445) had an average particle size of 0.239 microns and a median particle size of 0.206 microns with 10 volume percent greater than 0.446 microns.

At a pressure drop across the orifice of 30,000 psig, the slurry effluent comprising approximately 150 ml (813-446) had an average particle size of 0.197 microns and a median particle size of 0.155 microns with 10 volume percent greater than 0.386 microns.

At a pressure drop across the orifice of 45,000 psig, the slurry effluent comprising approximately 150 ml (813-447) had an average particle size of 0.181 microns and a median particle size of 0.137 microns with 10 volume percent greater than 0.364 microns.

When processing water through the machine following the above experimental runs, the machine was no longer capable of maintaining a 45,000 psig pressure drop across the nozzle, and the nozzle was replaced.

### Example 22

A liquefied filter cake of silica of the present invention (813-442) was pH adjusted from 6.28 to 9.99 with concentrated ammonium hydroxide (29.6 weight percent Assay) to provide silica slurry, this slurry having the same particle size distribution as (813-442). At a pressure drop of 45,000 psig, the resulting slurry effluent comprising of approximately 150 ml (813-450) had an average particle size of 0.156 microns and a median particle size of 0.124 microns with 10 volume percent greater than 0.303 microns.

Liquefied filter cake of silica of the current invention (813-442) was pH adjusted from 6.37 to 10.14 with concentrated sodium hydroxide (50% w/w) to provide silica slurry (813-444), this slurry having the same particle size distribution as (813-442). At a pressure drop of 25,000 psig, the resulting slurry effluent comprising of approximately 150 ml (813-451) had an average particle size of 0.179 microns and a median particle size of 0.136 microns with 10 volume percent greater than 0.306 micron.

The nozzle through which this slurry was passed was sufficiently worn such that the maximum obtainable pressure drop across the nozzle on a sample of similar characteristics was 25,000 psig.

Comparative Example of Silica Slurry Feed into Single Water jet

This examples demonstrate that the slurry composition from the method by which silica slurry is fed into a single water jet after the jet has been created, thereby eliminating wear on the alumina nozzle such that a suitable process intensity can be maintained. The slurry is then subjected to the subsequent reactor configuration described, and this process provides an effluent slurry having a particle size distribution characteristic of CMP slurries—i.e.—having a completely sub-micron particle size distribution at the higher operating pressure.

### Example 23

Slurry of silica the present invention (813-442) having an average particle size of 25.83 microns and a median particle size of 24.180 microns, with 10 volume percent greater then 45.09 microns was introduced on the low-pressure side of the alumina nozzle, not passing through the alumina nozzle, rather to an area of vacuum created by the water jet. The water jet, created at different pressure drops across the nozzle, was formed by a configuration comprising one nozzle of 0.1 mm I.D, configured to deliver a jet of water along a path into an elongated chamber containing reactors and seals, namely 11 alumina reactors with an internal diameter of 1.0 mm with alternating UHMWPE seals having an internal diameter of 2.6 mm, to the end of the interaction chamber where the stream was then reversed, flowing back through the interaction chamber, against the path of the original jet. The outlet port of the interaction chamber was directed to an open container in which the product slurry was collected.

A portion of the original silica slurry (813-442) was introduced into this single-jet cell between the water jet (from the 0.13 mm ID nozzle) and the elongated chamber, the water jet formed at a pressure drop of 20,000 psig. The resulting slurry effluent (813-448) had an average particle size of 0.723 microns and a median particle size of 0.230 microns with 10 volume percent greater than 1.913. The nozzle through which the water was passed showed no sign of degradation.

Another portion of the original silica slurry (813-442) was introduced into this single-jet cell between the water jet (from the 0.13 mm ID nozzle) and the elongated chamber, the water jet formed at a pressure drop of 40,000 psig. The resulting slurry effluent (813-449) had an average particle size of 0.211 microns and a median particle size of 0.156 microns with 10 volume percent greater than 0.432 microns. The nozzle through which the water was passed showed no sign of degradation.

Dual Jet, Dual Feed: Powder Feed into Water lets with Various Reactor Configurations

These examples demonstrate that the slurry composition from the method by which silica powder is fed to a dual-water jet configuration having the specifications of alumina reactors (1 reactor, 1 mm I.D.) and alternating UHMWPE seals (2.6 mm I.D.), does not provide an effluent slurry having a completely sub-micron particle size distribution, regardless of the operating pressure. They also demonstrate that the slurry composition from the method by which silica powder is fed to a dual-water jet configuration having the specifications of alumina reactors (5 reactors, 1 mm I.D. followed by 1 reactor, 0.5 mm I.D.) and alternating UHMWPE seals (2.6 mm I.D), does not provide an effluent slurry having a completely sub-micron particle size distribution when operating at 45,000 psig. They also demonstrate that the slurry composition from the method by which silica powder is fed to a dual-water jet configuration having the specifications of alumina reactors (6 reactors, 1 mm I.D.) and alternating UHMWPE seals (2.6 mm I.D.) does provide an effluent slurry having a completely sub-micron particle size distribution when operating at 45,000 psig.

### Example 24

Filter Cake (813-368) of silica of the present invention was liquefied under low shear with water to approximately 12 weight percent, and pH adjusted to approximately 6.3. A portion of this silica slurry when spray dried produced a white powder. Analysis of this powder (813-369) showed the following properties: Nitrogen BET (5 point) 158 m²/g; CTAB 152 m²/g. The calculated surface roughness is 1.0.

This spray-dried powder (813-369) was characterized as having an average particle size of 28.89 microns and a median particle size of 31.170 microns. Particle size reduction of a portion of this powder was conducted by using a double-jet cell that contained an elongated chamber of alumina reactors (1 reactors, 1 mm I.D.) and alternating UHMWPE seals (2.6 mm I.D.). Water was pressurized (30,000 psig) and passed through two nozzles (0.1 mm I.D. and 0.13 mm I.D.) to produce water jets that entered this elongated chamber from opposite directions. A portion of silica powder (813-369) was introduced into this double-jet cell between the dominant water jet (from the 0.13 mm ID nozzle) and the elongated chamber. The slurry effluent was discharged at atmospheric pressure from this double-jet dell through an opening between the recessive water jet (from the 0.1 mm nozzle) and the elongated chamber. This slurry (813-474) was 20.2 weight percent solids, and the aggregate particle size was characterized by laser light scattering as follows: average 16.51 microns; median 12.97 microns; and 10 volume percent greater than 40.19 microns.

### Example 25

Particle size reduction of another portion of this powder was conducted by using a double-jet cell that contained an elongated chamber of alumina reactors (1 reactors, 1 mm I.D.) and alternating UHMWPE seals (2.6 mm I.D.). Water was pressurized (45,000 psig) and passed through two nozzles (0.1 mm I.D. and 0.13 mm I.D.) to produce water jets that entered this elongated chamber from opposite directions. A portion of silica slurry (813-369) was introduced into this double-jet cell between the dominant water jet (from the 0.13 mm ID nozzle) and the elongated chamber. The slurry effluent was discharged at atmospheric pressure from this double-jet dell through an opening between the recessive water jet (from the 0.1 mm nozzle) and the elongated chamber. This slurry (813-473) was 14.9 weight percent solids, and the aggregate particle size was characterized by laser light scattering as follows: average 12.54 microns; median 7.313 microns; and 10 volume percent greater than 34.61 microns.

### Example 26

Particle size reduction of another portion of this powder was conducted by using a double-jet cell that contained an elongated chamber of alumina reactors (6 reactors, 1 mm I.D.) and alternating UHMWPE seals (2.6 mm I.D.). Water was pressurized (45,000 psig) and passed through two nozzles (0.1 mm I.D. and 0.13 mm I.D.) to produce water jets that entered this elongated chamber from opposite directions. A portion of silica powder (813-369) was introduced into this double-jet cell between the dominant water jet (from the 0.13 mm ID nozzle) and the elongated chamber. The slurry effluent was discharged at atmospheric pressure from this double-jet dell through an opening between the recessive water jet (from the 0.1 mm nozzle) and the elongated chamber. This slurry (813-477) was 7.4 weight percent solids, and the aggregate particle size was characterized by laser light scattering as follows: average 0.148 microns; median 0.121 microns; and 10 volume percent greater than 0.280 microns.

### Example 27

A spray dried silica powder of the current invention was prepared, analysis of this powder (810-541) showed the following properties: Nitrogen BET (5 point) 169 m²/g; CTAB 166 m²/g. The calculated surface roughness is 1.0.

Particle size reduction of a portion of this powder was conducted by using a double-jet cell that contained an elongated chamber of alumina reactors (alternating 1 mm ID alumina reactors and 0.5 mm ID alumina reactors each separated with an UHMWPE seal (2.6 mm I.D.). Water was pressurized (45,000 psig) and passed through two nozzles (0.1 mm I.D. and 0.13 mm I.D.) to produce water jets that entered this elongated chamber from opposite directions. Silica powder (810-541) was introduced into this double-jet cell between the dominant water jet (from the 0.13 mm ID nozzle) and the elongated chamber. The slurry effluent was discharged at atmospheric pressure from this double-jet dell through an opening between the recessive water jet (from the 0.1 mm nozzle) and the elongated chamber. This slurry (813-497) was 6.4 weight percent solids, and the aggregate particle size was characterized by laser light scattering as follows: average 0.827 microns; median 0.245 microns; and 10 volume percent greater than 2.867 microns.

### Example 28

Particle size reduction of another portion of this powder was conducted by using a double-jet cell that contained an elongated chamber of alumina reactors (5 reactors, 1 mm I.D. followed by 1 reactor, 0.5 mm I.D.) and alternating UHMWPE seals (2.6 mm I.D.), with the 0.5 mm I.D. reactor closest the discharge port. Water was pressurized (45,000 psig) and passed through two nozzles (0.1 mm I.D. and 0.13 mm I.D.) to produce water jets that entered this elongated chamber from opposite directions. A portion of silica powder (810-541) was introduced into this double-jet cell between the dominant water jet (from the 0.13 mm ID nozzle) and the elongated chamber. The slurry effluent was discharged at atmospheric pressure from this double-jet dell through an opening between the recessive water jet (from the 0.1 mm nozzle) and the elongated chamber. This slurry (813-498) was 2.9 weight percent solids, and the aggregate particle size was characterized by laser light scattering as follows: average 1.532 microns; median 0.302 microns; and 10 volume percent greater than 5.062 microns.

### Example 29

Particle size reduction of another portion of this powder was conducted by using a double-jet cell that contained an elongated chamber of alumina reactors (6 reactors, 1 mm I.D.) and alternating UHMWPE seals (2.6 mm I.D.). Water was pressurized (45,000 psig) and passed through two nozzles (0.1 mm I.D. and 0.13 mm I.D.) to produce water jets that entered this elongated chamber from opposite directions. A portion of silica powder (810-541) was introduced into this double-jet cell between the dominant water jet (from the 0.13 mm ID nozzle) and the elongated chamber. The slurry effluent was discharged at atmospheric pressure from this double-jet dell through an opening between the recessive water jet (from the 0.1 mm nozzle) and the elongated chamber This slurry (813-491) was 8.1 weight percent solids, and the aggregate particle size was characterized by laser light scattering as follows: average 0.149 microns; median 0.119 microns; and 10 volume percent greater than 0.289 microns.

### Example 30

Particle size reduction of another portion of this powder was conducted by using a double-jet cell that contained an elongated chamber of alumina reactors (6 reactors, 1 mm I.D.) and alternating UHMWPE seals (2.6 mm I.D.). Water was pressurized (45,000 psig) and passed through two nozzles (0.1 mm I.D. and 0.13 mm I.D.) to produce water jets that entered this elongated chamber from opposite directions. A portion of silica powder (810-541) was introduced into this double-jet cell between the dominant water jet (from the 0.13 mm ID nozzle) and the elongated chamber. The slurry effluent was discharged at atmospheric pressure from this double-jet dell through an opening between the recessive water jet (from the 0.1 mm nozzle) and the elongated chamber. This slurry (813-492) was 6.5 weight percent solids, and the aggregate particle size was characterized by laser light scattering as follows: average 0.134 microns; median 0.113 microns; and 10 volume percent greater than 0.233 microns.

Comparative Examples of Various Silica Powder Feed to Dual Jet, Dual Feed Configuration

These examples demonstrate that the slurry composition from the method by which silica powder is fed to a dual-water jet configuration having the specifications of alumina reactors (6 reactors, 1 mm I.D.) and alternating seals (2.6 mm I.D.) does not necessarily provide an effluent slurry having a completely sub-micron particle size distribution when operating at 45,000 psi. These examples indicate that the method for preparation of precipitated silica is critical to produce a slurry that is completely sub-micron by the dual jet, dual feed configuration.

### Example 31

HiSil 233 Powder (678-594) showed the following properties: Nitrogen BET (5 point) 133 m²/g; CTAB 135 m²/g; 201 ml of dibutyl phthalate per 100 gm of anhydrous powder. The calculated surface roughness is 1.0.

Particle size reduction of a portion of this powder was conducted by using a double-jet cell that contained an elongated chamber of alumina reactors (6 reactors, 1 mm I.D.) and alternating UHMWPE seals (2.6 mm I.D.). Water was pressurized (45,000 psig) and passed through two nozzles (0.1 mm I.D. and 0.13 mm I.D.) to produce water jets that entered this elongated chamber from opposite directions. A portion of silica powder (678-594, 6.2 weight percent moisture) was introduced into this double-jet cell between the dominant water jet (from the 0.13 mm ID nozzle) and the elongated chamber. The slurry effluent was discharged at atmospheric pressure from this double-jet dell through an opening between the recessive water jet (from the 0.1 mm nozzle) and the elongated chamber. This slurry (813-679) was 12.10 weight percent solids, and the aggregate particle size was characterized by laser light scattering as follows: average 28.04 microns; median 22.72 microns; and 10 volume percent greater than 52.20 microns.

### Example 32

HiSil 233 Powder (678-594) showed the following properties: Nitrogen BET (5 point) 133 m²/g; CTAB 135 m²/g; 201 ml of dibutyl phthalate per 100 gm of anhydrous powder. Particle size reduction of a portion of this powder was conducted by using a double-jet cell that contained an elongated chamber of alumina reactors (6 reactors, 1 mm I.D.) and alternating UHMWPE seals (2.6 mm I.D.). Water was pressurized (45,000 psig) and passed through two nozzles (0.1 mm I.D. and 0.13 mm I.D.) to produce water jets that entered this elongated chamber from opposite directions. A portion of silica powder (678-594, 6.2 weight percent moisture) was introduced into this double-jet cell between the dominant water jet (from the 0.13 mm ID nozzle) and the elongated chamber. The slurry effluent was discharged at atmospheric pressure from this double-jet dell through an opening between the recessive water jet (from the 0.1 mm nozzle) and the elongated chamber. This slurry (813-680) was 8.50 weight percent solids, and the aggregate particle size was characterized by laser light scattering as follows: average 12.85 microns; median 8.97 microns; and 10 volume percent greater than 29.75 microns.

### Example 33

HiSil SBG Powder (715-6532) showed the following properties: Nitrogen BET (5 point) 147 m²/g; 197 ml of dibutyl phthalate per 100 gm of anhydrous powder. Particle size reduction of a portion of this powder was conducted by using a double-jet cell that contained an elongated chamber of alumina reactors (6 reactors, 1 mm I.D.) and alternating UHMWPE seals (2.6 mm I.D.). Water was pressurized (45,000 psig) and passed through two nozzles (0.1 mm I.D. and 0.13 mm I.D.) to produce water jets that entered this elongated chamber from opposite directions. A portion of silica powder (715-6532) was introduced into this double-jet cell between the dominant water jet (from the 0.13 mm ID nozzle) and the elongated chamber. The slurry effluent was discharged at atmospheric pressure from this double-jet dell through an opening between the recessive water jet (from the 0.1 mm nozzle) and the elongated chamber. This slurry (813-686) was 10.50 weight percent solids, and the aggregate particle size was characterized by laser light scattering as follows: average 2.528 microns; median 0.251 microns; and 10 volume percent greater than 8.970 microns.

### Example 34

HiSil SBG Powder (715-6532) showed the following properties: Nitrogen BET (5 point) 147 m²/g; 197 ml of dibutyl phthalate per 100 gm of anhydrous powder. Particle size reduction of a portion of this powder was conducted by using a double-jet cell that contained an elongated chamber of alumina reactors (6 reactors, 1 mm I.D.) and alternating UHMWPE seals (2.6 mm I.D.). Water was pressurized (45,000 psig) and passed through two nozzles (0.1 mm I.D. and 0.13 mm I.D.) to produce water jets that entered this elongated chamber from opposite directions. A portion of silica powder (715-6532) was introduced into this double-jet cell between the dominant water jet (from the 0.13 mm ID nozzle) and the elongated chamber. The slurry effluent was discharged at atmospheric pressure from this double-jet dell through an opening between the recessive water jet (from the 0.1 mm nozzle) and the elongated chamber. This slurry (813-687) was 11.60 weight percent solids, and the aggregate particle size was characterized by laser light scattering as follows: average 2.487 microns; median 0.244 microns; and 10 volume percent greater than 8.881 microns.

### Example 35

HiSil SBG Powder (715-6532) showed the following properties: Nitrogen BET (5 point) 147 m²/g; 197 ml of dibutyl phthalate per 100 gm of anhydrous powder. Particle size reduction of a portion of this powder was conducted by using a double-jet cell that contained an elongated chamber of alumina reactors (6 reactors, 1 mm I.D.) and alternating UHMWPE seals (2.6 mm I.D.). Water was pressurized (45,000 psig) and passed through two nozzles (0.1 mm I.D. and 0.13 mm I.D.) to produce water jets that entered this elongated chamber from opposite directions. A portion of silica powder (715-6532) was introduced into this double-jet cell between the dominant water jet (from the 0.13 mm ID nozzle) and the elongated chamber. The slurry effluent was discharged at atmospheric pressure from this double-jet dell through an opening between the recessive water jet (from the 0.1 mm nozzle) and the elongated chamber. This slurry (813-688) was 13.70 weight percent solids, and the aggregate particle size was characterized by laser light scattering as follows: average 2.469 microns; median 0.257 microns; and 10 volume percent greater than 8.835 microns.

### Example 36

HiSil 2000 Powder (623-1800) showed the following properties: Nitrogen BET (5 point) 234 m²/g; CTAB 232 m²/g; 326 ml of dibutyl phthalate per 100 gm of anhydrous powder. The calculated surface roughness is 1.0.

Particle size reduction of a portion of this powder was conducted by using a double-jet cell that contained an elongated chamber of alumina reactors (6 reactors, 1 mm I.D.) and alternating UHMWPE seals (2.6 mm I.D.). Water was pressurized (45,000 psig) and passed through two nozzles (0.1 mm I.D. and 0.13 mm I.D.) to produce water jets that entered this elongated chamber from opposite directions. A portion of silica powder (623-1800) was introduced into this double-jet cell between the dominant water jet (from the 0.13 mm ID nozzle) and the elongated chamber. The slurry effluent was discharged at atmospheric pressure from this double-jet dell through an opening between the recessive water jet (from the 0.1 mm nozzle) and the elongated chamber. This slurry (623-1801) was 10.96 weight percent solids, and the aggregate particle size was characterized by laser light scattering as follows: average 8.484 microns; median 0.402 microns; and 10 volume percent greater than 23.67 microns.

In the claims:

1. A silica comprising:
(a) an aggregate of primary particles, said primary particles having an average diameter of at least seven (7) nanometers, wherein said aggregate has an aggregate size of less than one (1) micron; and
(b) a hydroxyl content of at least seven (7) hydroxyl groups per nanometer squared.

2. The silica of claim 1 wherein said average diameter of said primary particles is at least ten (10) nanometers.

3. The silica of claim 1 wherein said average diameter of said primary particles is at least fifteen (15) nanometers.

4. The silica of claim 1 wherein said hydroxyl content is at least ten (10) hydroxyl groups per nanometer squared.

5. The silica of claim 1 wherein said hydroxyl content is at least fifteen (15) hydroxyl groups per nanometer squared.

6. The silica of claim 1 wherein said aggregate size is less than 0.5 micron.

7. A slurry composition comprising a silica which comprises:
(a) an aggregate of primary particles, said primary particles having an average diameter of at least seven (7) nanometers, wherein said aggregate has an aggregate size of less than one (1) micron;
(b) a hydroxyl content of at least seven (7) hydroxyl groups per nanometer squared; and
(c) a liquid.

8. The silica of claim 7 wherein said average diameter of said primary particles is at least ten (10) nanometers.

9. The silica of claim 7 wherein said average diameter of said primary particles is at least fifteen (15) nanometers.

10. The silica of claim 7 wherein said hydroxyl content is at least ten (10) hydroxyl groups per nanometer squared.

11. The silica of claim 7 wherein said hydroxyl content is at least fifteen (15) hydroxyl groups per nanometer squared.

12. A method of chemical mechanical planarization a substrate comprising the step of applying a slurry composition which comprises a silica, said silica comprising:
(a) an aggregate of primary particles, said primary particles having an average diameter of at least seven (7) nanometers, wherein said aggregate has an aggregate size of less than one (1) micron; and
(b) a hydroxyl content of at least seven (7) hydroxyl groups per nanometer squared.

13. The method of claim 12 wherein said chemical mechanical planarization comprises removing from said substrate materials selected from the group consisting of metals, metal oxides and polymer dielectrics.

14. The method of claim 12 wherein said chemical mechanical planarization comprises removing from said substrate elements selected from the group consisting of copper, tantalum, tungsten and aluminum.

15. The method of claim 12 wherein said chemical mechanical planarization comprises removing silicon dioxide from said substrate.

16. The method of claim 12 wherein said chemical mechanical planarization comprises removing copper and tantalum from said substrate.

17. The method of claim 16 wherein said removal of tantalum is at a rate which is equal to or greater than said removal of copper.

18. A slurry composition for chemical mechanical planarization of a substrate comprising a silica comprising an aggregate of primary particles, wherein said silica has a BET to CTAB ratio of greater than 1.

19. The slurry composition of claim 18 wherein said aggregate of said silica has an aggregate size of less than one (1) micron.

20. The slurry composition of claim 18 wherein said primary particles of said silica have an average diameter of greater than seven (7) nanometers.

21. The slurry composition of claim 18 wherein said silica has a hydroxyl content of greater than seven (7) hydroxyl groups per nanometer squared.

22. A slurry composition for chemical mechanical planarization of a substrate comprising a silica comprising an aggregate of primary particles, said aggregate having an aggregate size of less than one (1) micron, wherein said silica has an oil absorption value of at least 150 milliliters per 100 grams of silica.

23. The slurry composition of claim 22 wherein said oil absorption value is at least 220 milliliters per 100 grams of silica.

24. The silica of claim 1 wherein the said silica comprises a precipitated silica.

25. A precipitated silica comprising:
(a) an aggregate of primary particles, said primary particles having an average diameter of at least seven (7) nanometers, wherein said aggregate has an aggregate size of less than one (1) micron; and
(b) a hydroxyl content of at least seven (7) hydroxyl groups per nanometer squared.

26. The precipitated silica of claim 25 wherein said average diameter of said primary particles is at least ten (10) nanometers.

27. The precipitated silica of claim 25 wherein said average diameter of said primary particles is at least fifteen (15) nanometers.

28. The precipitated silica of claim 25 wherein said hydroxyl content is at least ten (10) hydroxyl groups per nanometer squared.

29. The precipitated silica of claim 25 wherein said hydroxyl content is at least fifteen (15) hydroxyl groups per nanometer squared.

30. The slurry composition of claim 7 wherein said silica comprises a precipitated silica.

31. The slurry composition of claim 7 wherein said slurry is applied to a substrate for chemical mechanical planarization of said substrate.

32. A slurry composition for chemical mechanical planarization of a substrate comprising a precipitated silica which comprises:
(a) an aggregate of primary particles, said primary particles having an average diameter of at least seven (7) nanometers, wherein said aggregate has an aggregate size of less than one (1) micron; and
(b) a hydroxyl content of at least seven (7) hydroxyl groups per nanometer squared.

33. The slurry composition of claim 18 wherein said BET to CTAB ratio is at least 1.2 or greater.

34. A silica capable of being reduced to an aggregate size of less than one (1) micron by employing a wet milling process.

35. A precipitated silica capable of being reduced to an aggregate size of less than one (1) micron by employing a wet milling process.
